(19) United States
(12) Patent Application Publication
(10) Pub. No.: US 2026/0150315 A1
(43) Pub. Date: May 28, 2026

(54) SEMICONDUCTOR DEVICE AND METHOD OF MANUFACTURING THE SAME

(71) Applicant: Renesas Electronics Corporation, Tokyo (JP)

(72) Inventors: Kouichi KONISHI, Tokyo (JP); Takahiro MARUYAMA, Tokyo (JP); Takuho KAMADA, Tokyo (JP); Tohru KAWAI, Tokyo (JP)

(21) Appl. No.: 19/178,536

(22) Filed: Apr. 14, 2025

(30) Foreign Application Priority Data
May 23, 2024 (JP) 2024-083982

(51) Int. Cl. H10D 12/00; H10D 12/01; H10D 62/10; H10D 64/27; H10D 64/62; H10P 50/26; H10P 50/28

(52) U.S. Cl. CPC H10D 12/461; H10D 12/035; H10D 12/038; H10D 12/415; H10D 64/518; H10D 64/62; H10P 50/26; H10P 50/28; H10D 62/102

(57) ABSTRACT

To provide a semiconductor device capable of preventing a contact barrier metal film from peeling off from the trench gate lead-out electrode. In the gate wiring lead-out region MGR defined on a semiconductor substrate, a convex portion is formed on the trench gate lead-out electrode TGI, extending towards a gate lead-out contact member. The convex portion is formed by a natural oxidation film and a polysilicon film PSF. The gate lead-out contact member is formed to cover the convex portion by interposing the contact barrier metal film.

### CROSS-REFERENCE TO RELATED APPLICATIONS

The disclosure of Japanese Patent Application No. 2024-083982 filed on May 23, 2024, including the specification, drawings and abstract is incorporated herein by reference in its entirety.

### BACKGROUND

The present invention relates to a semiconductor device and its manufacturing method, and can be suitably applied to a semiconductor device equipped with an electron injection enhancement type trench insulated gate bipolar transistor.

In power semiconductor devices, there are semiconductor devices equipped with trench insulated gate bipolar transistors (IGBTs) as switching elements. Furthermore, there are semiconductor devices that enhance the Injection Enhancement (IE) effect to lower the on-voltage.

In this type of semiconductor device, a region is formed to suppress holes injected from the collector side from escaping to the emitter (electrode) side. This increases the concentration of holes accumulated in the drift layer of a semiconductor substrate, promoting electron injection from the emitter side and increasing the electron concentration. The increased concentration of carriers (electrons and holes) causes conductivity modulation, allowing the on-voltage to be lowered. Various arrangement patterns of trench gate electrodes have been proposed for this type of semiconductor device depending on the application.

The IGBT is formed in the cell region. Outside the cell region, a trench gate lead-out electrode electrically connected to the trench gate electrode of the IGBT is formed. The trench gate lead-out electrode is formed to have a width (wide portion) wider than the width of the trench gate electrode. The trench gate lead-out electrode is electrically connected to the gate electrode via a gate lead-out contact member and gate lead-out wiring.

The gate lead-out contact member is formed in a contact opening formed in an interlayer insulating film covering the main surface of the semiconductor substrate. The gate lead-out contact member is electrically connected to the trench gate lead-out electrode via a contact barrier metal film. The gate lead-out wiring is formed on the interlayer insulating film with an interlayer barrier metal film interposed (Patent Document 1).

There is disclosed a technique listed below.
[Patent Document 1] Japanese Unexamined Patent Application Publication No. 2022-82244

### SUMMARY

In the aforementioned semiconductor device, heat treatment is applied to ensure adhesion between an interlayer insulating film and the interlayer barrier metal film. During this heat treatment, it was confirmed that the contact barrier metal film peels off from the trench gate lead-out electrode.

Other objects and novel features will become apparent from the description of this specification and the accompanying drawings.

A semiconductor device according to one embodiment includes a semiconductor substrate of a first conductivity type, a plurality of trench electrodes, an interlayer insulating film, a contact barrier metal film, a plurality of contact members, and an interlayer barrier metal film. The semiconductor substrate of the first conductivity type has opposing first and second main surfaces, with a plurality of trenches formed from the first main surface toward the second main surface. The plurality of trench electrodes is formed in each of the plurality of trenches. The interlayer insulating film is formed to cover the first main surface of the semiconductor substrate, with a plurality of contact openings reaching each of the plurality of trench electrodes. The contact barrier metal film is formed on the inner walls of each of the plurality of contact openings. The plurality of contact members is formed in each of the plurality of contact openings with the contact barrier metal film interposed, and are electrically connected to each of the plurality of trench electrodes. The interlayer barrier metal film is formed to contact the interlayer insulating film. The plurality of trenches formed in the semiconductor substrate includes a first trench. The plurality of trench electrodes includes a first trench electrode formed in the first trench. The plurality of contact openings formed in the interlayer insulating film includes a first contact opening reaching the first trench electrode. The plurality of contact members includes a first contact member electrically connected to the first trench electrode. A convex portion is formed on the first trench electrode located at the bottom of the first contact opening, projecting toward the first contact member. In the first contact opening, the contact barrier metal film is formed to cover the convex portion. The first contact member is formed in the first contact opening with the contact barrier metal film interposed to cover the convex portion.

A method of manufacturing a semiconductor device according to another embodiment includes the following steps. Preparing a semiconductor substrate of a first conductivity type having opposing first and second main surfaces. Forming a plurality of trenches from the first main surface toward the second main surface of the semiconductor substrate. Forming a plurality of trench electrodes in each of the plurality of trenches. Form an interlayer insulating film to cover the first main surface of the semiconductor substrate. Perform a first etching process on the interlayer insulating film to form a plurality of contact openings exposing each of the plurality of trench electrodes. Perform a second etching process on the exposed plurality of trench electrodes. Forming a contact barrier metal film on the inner walls of each of the plurality of contact openings. Forming a plurality of contact members in each of the plurality of contact openings with the contact barrier metal film interposed. Forming an interlayer barrier metal film to contact the interlayer insulating film and the plurality of contact members. After forming the interlayer barrier metal film, perform heat treatment. The step of forming the plurality of trenches includes forming a first trench. The step of forming the plurality of trench electrodes includes forming a first trench electrode in the first trench. The step of forming the plurality of contact openings by the first etching process includes forming a first contact opening exposing the first trench electrode. The step of forming the contact barrier metal film includes forming a first contact barrier metal film on the inner wall of the first contact opening, including the first trench electrode exposed at the bottom of the first contact opening. The step of forming the plurality of contact members includes forming a first contact member in the first contact opening with the first contact barrier metal film interposed. In the step of performing the second etching process, a convex portion is formed on the first trench electrode, projecting toward the first contact member. In the step of forming the first contact barrier metal film, the first contact barrier metal film is formed in the first contact opening in a manner covering the convex portion. In the step of forming the first contact member, the first contact member is formed in the first contact opening with the first contact barrier metal film interposed to cover the convex portion.

According to one embodiment of the semiconductor device, it is possible to prevent the contact barrier metal film from peeling off from the trench gate lead-out electrode.

According to the manufacturing method of the semiconductor device according to another embodiment, it is possible to manufacture a semiconductor device that prevents the contact barrier metal film from peeling off from the trench gate lead-out electrode.

### BRIEF DESCRIPTION OF THE DRAWINGS

FIG. 1 is a plan view showing an example of a semiconductor device according to each embodiment.

FIG. 2 is a partial plan view showing an example of the planar structure of a semiconductor device according to the first embodiment.

FIG. 3 is a cross-sectional view showing the cross-sectional structures along cross-sectional lines IIIa-IIIa, IIIb-IIIb, and IIIc-IIIc shown in FIG. 2 in the same embodiment.

FIG. 4 is a partially enlarged cross-sectional view of the gate wiring lead-out area in the same embodiment.

FIG. 5 is a cross-sectional view showing a step in the manufacturing method of the semiconductor device in the same embodiment.

FIG. 6 is a cross-sectional view showing a step performed after the process shown in FIG. 5 in the same embodiment.

FIG. 7 is a cross-sectional view showing a step performed after the process shown in FIG. 6 in the same embodiment.

FIG. 8 is a cross-sectional view showing a step performed after the process shown in FIG. 7 in the same embodiment.

FIG. 9 is a cross-sectional view showing a step performed after the process shown in FIG. 8 in the same embodiment.

FIG. 10 is a cross-sectional view showing a step performed after the process shown in FIG. 9 in the same embodiment.

FIG. 11 is a cross-sectional view showing a step performed after the process shown in FIG. 10 in the same embodiment.

FIG. 12 is a cross-sectional view showing a step performed after the process shown in FIG. 11 in the same embodiment.

FIG. 13 is a cross-sectional view showing a step performed after the process shown in FIG. 12 in the same embodiment.

FIG. 14 is a cross-sectional view showing a step performed after the process shown in FIG. 13 in the same embodiment.

FIG. 15 is a cross-sectional view showing a step performed after the process shown in FIG. 14 in the same embodiment.

FIG. 16 is a cross-sectional view showing a step performed after the process shown in FIG. 15 in the same embodiment.

FIG. 17 is a partially enlarged cross-sectional view of the process shown in FIG. 16 in the same embodiment.

FIG. 18 is a cross-sectional view showing a step performed after the process shown in FIG. 16 in the same embodiment.

FIG. 19 is a partially enlarged cross-sectional view of the process shown in FIG. 18 in the same embodiment.

FIG. 20 is a cross-sectional view showing a step performed after the process shown in FIG. 18 in the same embodiment.

FIG. 21 is a partially enlarged cross-sectional view of the process shown in FIG. 20 in the same embodiment.

FIG. 22 is a cross-sectional view showing a step performed after the process shown in FIG. 20 in the same embodiment.

FIG. 23 is a cross-sectional view showing a step performed after the process shown in FIG. 22 in the same embodiment.

FIG. 24 is a cross-sectional view showing a step performed after the process shown in FIG. 23 in the same embodiment.

FIG. 25 is a cross-sectional view showing a step performed after the process shown in FIG. 24 in the same embodiment.

FIG. 26 is a diagram showing the simulation results of the film stress acting on a contact barrier metal film interposed between the trench gate lead-out electrode and a gate lead-out contact member in a semiconductor device according to a comparative example.

FIG. 27 is a diagram showing the simulation results of the film stress acting on the contact barrier metal film interposed between the trench gate lead-out electrode and the gate lead-out contact member in the same embodiment.

FIG. 28 is a partial plan view showing an example of the planar structure of a semiconductor device according to the second embodiment.

FIG. 29 is a cross-sectional view showing the cross-sectional structures along cross-sectional lines XXIXa-XXIXa, XXIXb-XXIXb, and XXIXc-XXIXc shown in FIG. 28 in the same embodiment.

FIG. 30 is a cross-sectional view showing a step in the manufacturing method of the semiconductor device in the same embodiment.

FIG. 31 is a cross-sectional view showing a step performed after the process shown in FIG. 30 in the same embodiment.

FIG. 32 is a cross-sectional view showing a step performed after the process shown in FIG. 31 in the same embodiment.

FIG. 33 is a cross-sectional view showing a step performed after the process shown in FIG. 32 in the same embodiment.

FIG. 34 is a cross-sectional view showing a step performed after the process shown in FIG. 33 in the same embodiment.

FIG. 35 is a cross-sectional view showing a step performed after the process shown in FIG. 34 in the same embodiment.

FIG. 36 is a cross-sectional view showing a step performed after the process shown in FIG. 35 in the same embodiment.

FIG. 37 is a cross-sectional view showing a step performed after the process shown in FIG. 36 in the same embodiment.

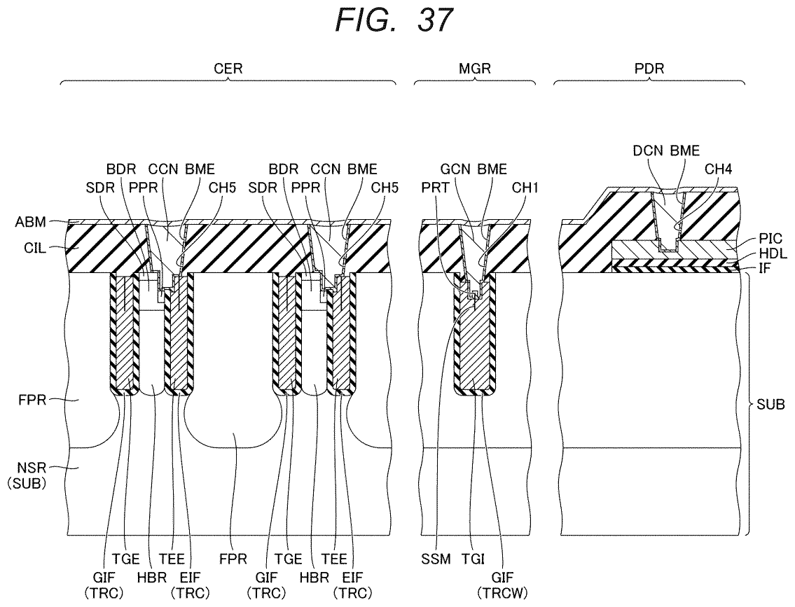

FIG. 38 is a cross-sectional view showing an example of the cross-sectional structure of a semiconductor device according to the third embodiment.

### DETAILED DESCRIPTION

In a semiconductor device equipped with an IE-type trench insulated gate bipolar transistor, it is mentioned that there are various arrangement patterns of trench gate electrodes depending on the application. For instance, in semiconductor devices that emphasize the reduction of on-voltage, there is a GE-type semiconductor device. The GE-type structure is characterized by a trench gate electrode electrically connected to the gate electrode and a trench emitter electrode electrically connected to the emitter electrode, arranged with a gap between them.

Additionally, in semiconductor devices that emphasize operational stability and balance, there is a GGEE-type semiconductor device. The GGEE-type structure features one trench emitter electrode and another trench emitter electrode arranged with a gap between them, and one trench gate electrode and another trench gate electrode also arranged with a gap between them. The one trench emitter electrode and the other trench emitter electrode, as well as the one trench gate electrode and the other trench gate electrode, are arranged with a predetermined interval between them.

Furthermore, in semiconductor devices that emphasize high-speed performance, there is an EGE-type semiconductor device. The EGE-type structure consists of one trench emitter electrode, a trench gate electrode, and another trench emitter electrode, each arranged with a gap between them. The specifics will be explained below.

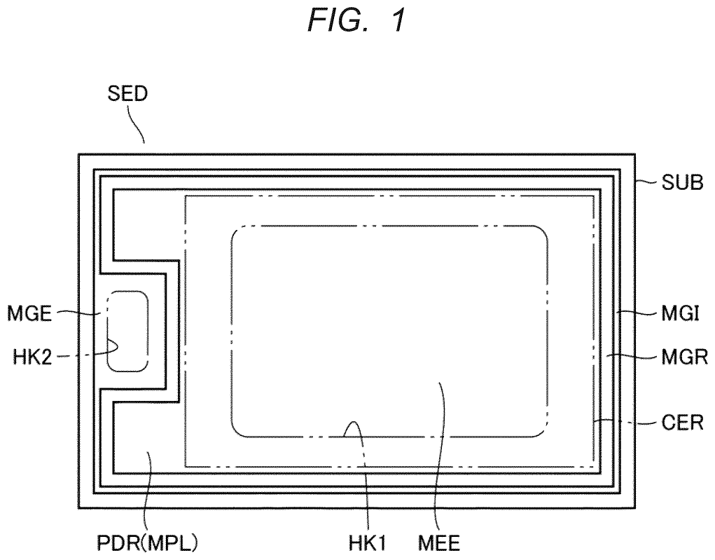

First, an example of the overall structure of a semiconductor device equipped with an IE-type trench insulated gate bipolar transistor will be described. As shown in FIG. 1, in the semiconductor device SED (semiconductor substrate SUB), a cell region CER and a gate wiring lead-out region MGR are defined.

In the cell region CER, an IE-type trench insulated gate bipolar transistor is formed. The cell region CER is covered by an emitter electrode MEE. The emitter electrode MEE is exposed at the bottom of an opening HK1 formed in an insulating film (not shown) covering the emitter electrode MEE (semiconductor substrate SUB).

The gate wiring lead-out region MGR is arranged to surround the cell region CER. In the gate wiring lead-out region MGR, a gate lead-out wiring MGI and a gate electrode MGE are formed. The gate lead-out wiring MGI is electrically connected to the gate electrode MGE. The gate electrode MGE is exposed at the bottom of an opening HK2 formed in an insulating film (not shown) covering the gate electrode MGE (semiconductor substrate SUB).

Furthermore, in the semiconductor device SED (semiconductor substrate SUB), a peripheral element region PDR, where peripheral elements such as a protection diode or a temperature sensing diode are formed, is defined.

### First Embodiment

Here, an example of a GGEE-type semiconductor device will be described. The GGEE-type semiconductor device is applied to applications requiring stable operation, etc. First, the cell region CER will be described.

### Cell Region CER

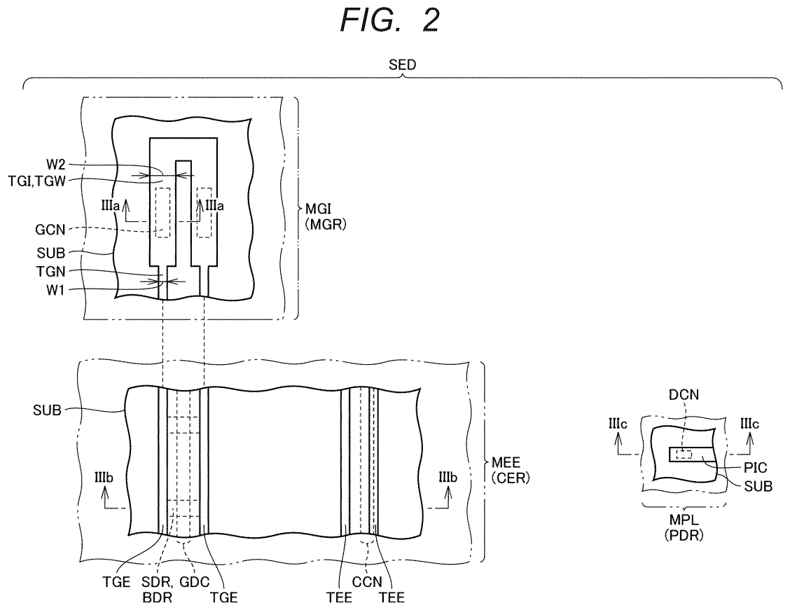

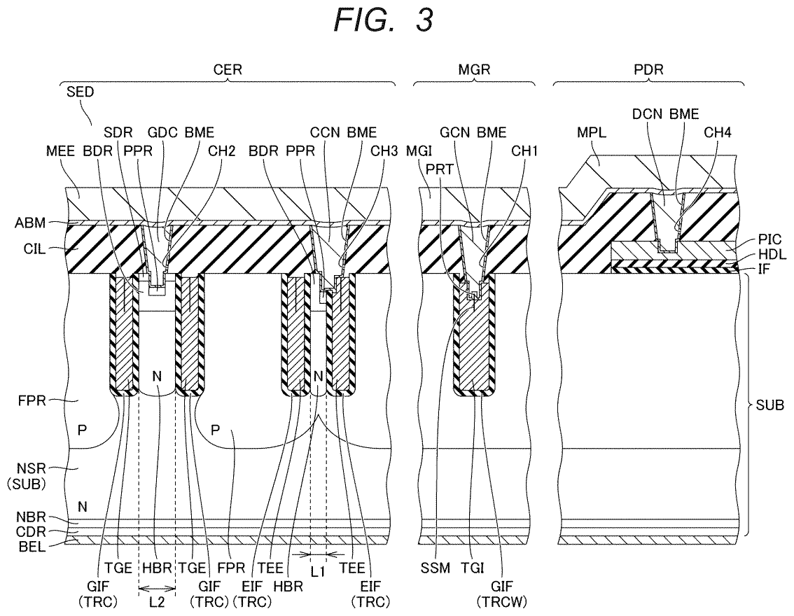

As shown in FIGS. 2 and 3, in the cell region CER on a first main surface side of the semiconductor substrate SUB, one trench emitter electrode TEE (third trench electrode) and another trench emitter electrode TEE (fourth trench electrode) are arranged at a distance in one direction. The interval between one trench emitter electrode TEE and the other trench emitter electrode TEE is interval L1. The one trench emitter electrode TEE and the other trench emitter electrode TEE extend in another direction intersecting the one direction.

One trench gate electrode TGE (second trench electrode) and another trench gate electrode TGE are arranged at a distance in one direction. The interval between one trench gate electrode TGE and the other trench gate electrode TGE is interval L2. Interval L2 is larger than interval L1. The one trench gate electrode TGE and the other trench gate electrode TGE extend in another direction intersecting the one direction.

Additionally, one trench emitter electrode TEE and another trench emitter electrode TEE, and one trench gate electrode TGE and another trench gate electrode TGE are arranged at a distance in one direction. In the region of the semiconductor substrate SUB located between one trench gate electrode TGE and another trench gate electrode TGE, an N+type source diffusion layer SDR is formed.

From the bottom of the source diffusion layer SDR to a further predetermined depth, a P-type base diffusion layer BDR is formed. In the base diffusion layer BDR, a P+ layer PPR with a higher P-type impurity concentration is formed. From the bottom of the base diffusion layer BDR to a further predetermined depth, an N-type hole barrier layer HBR is formed. The hole barrier layer HBR is formed to the extent that it reaches the bottom (lower end) of one trench gate electrode TGE and another trench gate electrode TGE. The region where the hole barrier layer HBR is formed is referred to as the active region.

In the region of the semiconductor substrate SUB located between one trench emitter electrode TEE and another trench emitter electrode TEE, a P-type base diffusion layer BDR is formed from the first main surface to a predetermined depth. In the base diffusion layer BDR, a P+ layer PPR with a higher P-type impurity concentration is formed. From the bottom of the base diffusion layer BDR to a further predetermined depth, an N-type hole barrier layer HBR is formed. The hole barrier layer HBR is formed to the extent that it reaches the bottom (lower end) of one trench emitter electrode TEE and another trench emitter electrode TEE. The region where the hole barrier layer HBR is formed is referred to as the active region.

In the region of the semiconductor substrate SUB where one trench emitter electrode TEE and another trench emitter electrode TEE are arranged with respect to one trench gate electrode TGE and another trench gate electrode TGE, a P-type floating diffusion layer FPR is formed from the first main surface to a position deeper than the bottom (lower end) of one trench emitter electrode TEE and another trench emitter electrode TEE. The floating diffusion layer FPR is referred to as the inactive region.

### Gate Wiring Lead-Out Region MGR

In the gate wiring lead-out region MGR, a trench gate lead-out electrode TGI (first trench electrode) is formed. The trench gate lead-out electrode TGI is formed in a trench TRCW (first trench) with a trench insulating film GIF interposed. As will be described later, a convex portion PRT protruding toward a gate lead-out contact member GCN is formed on the trench gate lead-out electrode TGI. A height H of the convex portion PRT is at least 50 nm or more.

As shown in FIGS. 2 and 3, the trench gate lead-out electrode TGI is electrically connected to the trench gate electrode TGE. The trench gate lead-out electrode TGI (trench TRCW) has a first part TGN set to a first width W1 as the width of the trench gate electrode TGE (trench TRC) and a second part TGW set to a second width W2 wider than the first width W1.

### Peripheral Element Region PDR

In the peripheral element region PDR, wiring PIC is formed on the first main surface of the semiconductor substrate SUB with an insulating film IF and a silicon oxide film HDL interposed. The wiring PIC is electrically connected to peripheral elements (not shown) such as a protection diode or a temperature sensing diode.

### Structure on Semiconductor Substrate SUB

Next, the structure on the semiconductor substrate SUB will be described. An interlayer insulating film CIL is formed on the semiconductor substrate SUB to cover the trench gate electrode TGE, trench emitter electrode TEE, trench gate lead-out electrode TGI, and the like.

In the cell region CER, contact openings CH2 and CH3 are formed to penetrate the interlayer insulating film CIL. In the contact opening CH2, a gate contact member GDC is formed with a contact barrier metal film BME interposed. In the contact opening CH3, a shared contact member CCN (second contact member) is formed with the contact barrier metal film BME interposed.

On the surface of the interlayer insulating film CIL, an emitter electrode MEE is formed with an interlayer barrier metal film ABM interposed. The gate contact member GDC and the shared contact member CCN are electrically connected to the emitter electrode MEE. The emitter electrode MEE is formed of, for example, an aluminum film.

In the gate wiring lead-out region MGR, a contact opening CH1 is formed to penetrate the interlayer insulating film CIL. In the contact opening CH1, a gate lead-out contact member GCN (first contact member) is formed with the contact barrier metal film BME interposed. On the surface of the interlayer insulating film CIL, a gate lead-out wiring MGI is formed with the interlayer barrier metal film ABM interposed. The gate lead-out wiring MGI is formed of, for example, an aluminum film.

In the peripheral element region PDR, a contact opening CH4 is formed to penetrate the interlayer insulating film CIL. In the contact opening CH4, a contact member DCN contacting the wiring PIC is formed with the contact barrier metal film BME interposed. On the surface of the interlayer insulating film CIL, a conductive layer MPL is formed with the interlayer barrier metal film ABM interposed. The contact member DCN is electrically connected to the conductive layer MPL.

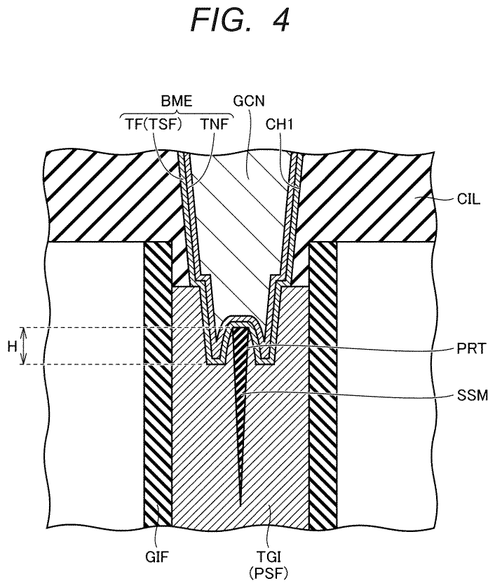

The contact barrier metal film BME is formed as a laminated film of a titanium film TF (lower layer) and a titanium nitride film TNF (upper layer). The contact barrier metal film BME includes titanium silicide TSF, which is formed by silicide a part of the titanium film TF (see FIG. 4). As the interlayer barrier metal film ABM, for example, a titanium-tungsten film is formed.

Next, the structure of the trench gate lead-out electrode TGI in the gate wiring lead-out region MGR will be described. As shown in FIG. 4, the trench gate lead-out electrode TGI has the convex portion PRT formed extending towards the gate lead-out contact member GCN.

The trench gate lead-out electrode TGI has a natural oxidation film SSM formed protruding towards the gate lead-out contact member GCN. A polysilicon film PSF, which constitutes the trench gate lead-out electrode TGI, is formed to cover the side surface of the natural oxidation film SSM. The convex portion PRT is formed by the natural oxidation film SSM and the polysilicon film PSF. The convex portion PRT is formed along the direction in which the trench gate lead-out electrode TGI extends.

The gate lead-out contact member GCN is formed to cover the convex portion PRT by interposing the contact barrier metal film BME. As will be described later, the contact barrier metal film BME is formed to cover the convex portion PRT in the gate lead-out contact member GCN, which can suppress the peeling of the contact barrier metal film BME.

On the other hand, on a second main surface side of the semiconductor substrate SUB, a P-type collector diffusion layer CDR and an N-type buffer layer NBR are formed. An N-type region NSR, serving as a drift layer, is positioned between the floating diffusion layer FPR and the buffer layer NBR. A collector electrode BEL (bottom surface electrode) is formed to contact the collector diffusion layer CDR (the second main surface of the semiconductor substrate SUB). The GGEE-type semiconductor device SED is configured as described above.

### Manufacturing Method

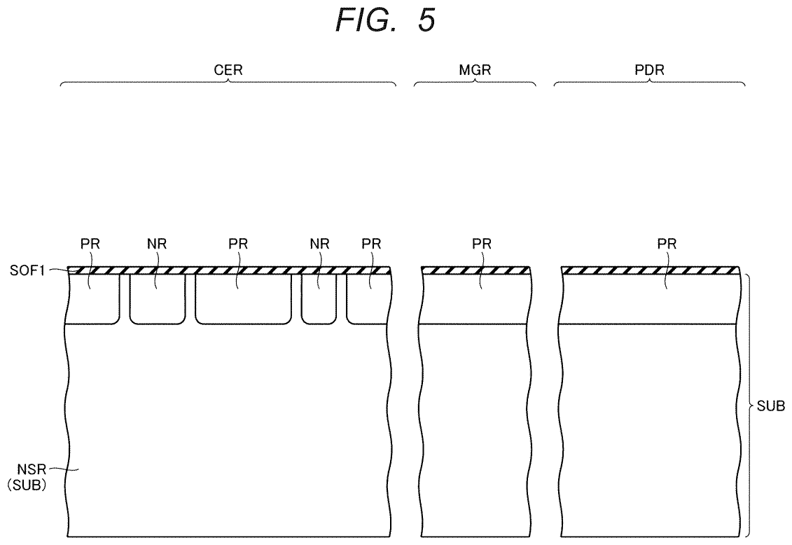

Next, an example of the manufacturing method for the aforementioned semiconductor device SED will be described. As shown in FIG. 5, a silicon oxide film SOF1 is formed to cover the first main surface of the semiconductor substrate SUB. Then, with the silicon oxide film SOF1 formed, a P-type region PR, which will become a floating diffusion layer, is formed by implanting P-type impurities. Additionally, an N-type region NR, which will become a hole barrier layer, is formed by implanting N-type impurities.

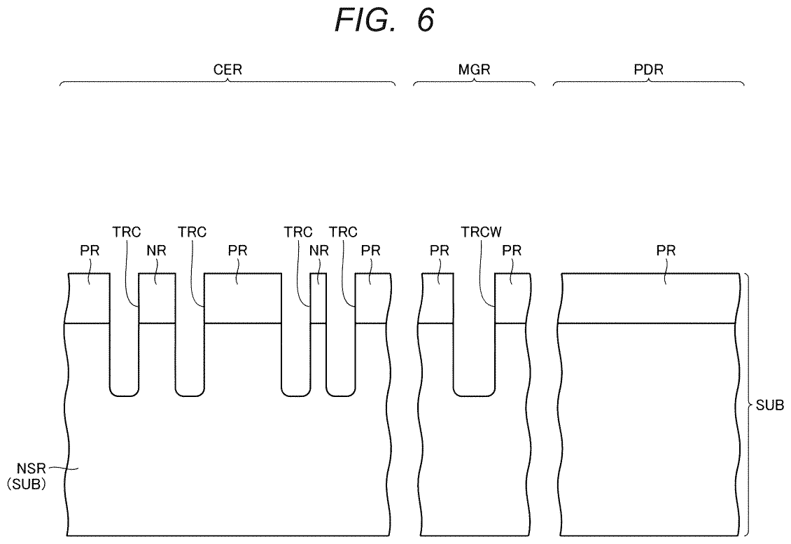

Next, a hard mask (not shown) for forming a plurality of trenches is created. Then, using this hard mask as an etching mask, etching is performed on the semiconductor substrate SUB to form the plurality of trenches TRC (second trench, third trench and fourth trench) and the trench TRCW (first trench) (see FIG. 6). Subsequently, the hard mask is removed. As a result, as shown in FIG. 6, the first main surface of the semiconductor substrate SUB, where the plurality of trenches TRC and TRCW are formed, is exposed. The trench TRCW is formed to have a wider width than trench TRC.

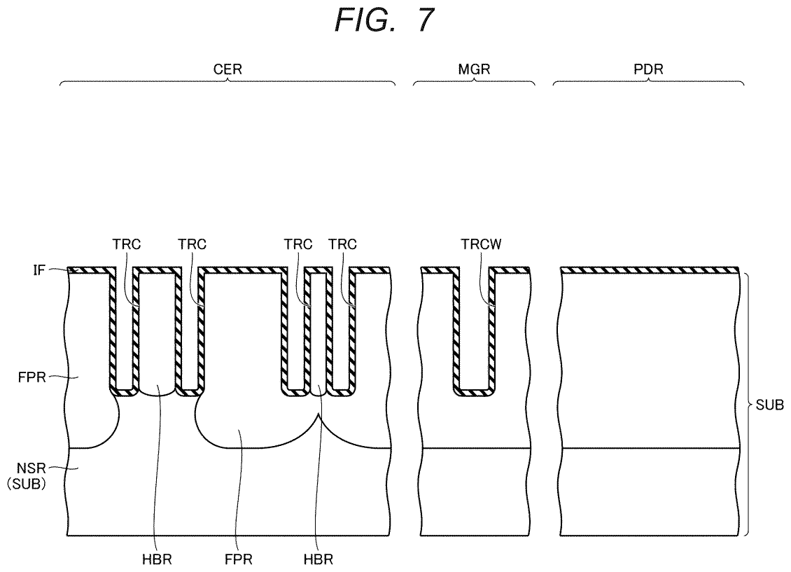

Next, by applying a predetermined heat treatment, the P-type impurities in the P-type region PR diffuse, forming a floating diffusion layer FPR. Similarly, the N-type impurities in the N-type region NR diffuse, forming a hole barrier layer HBR (see FIG. 7). Then, as shown in FIG. 7, by performing thermal oxidation treatment, an insulating film IF is formed on the first main surface of the semiconductor substrate SUB, including the inner wall surfaces of the plurality of trenches TRC and TRCW.

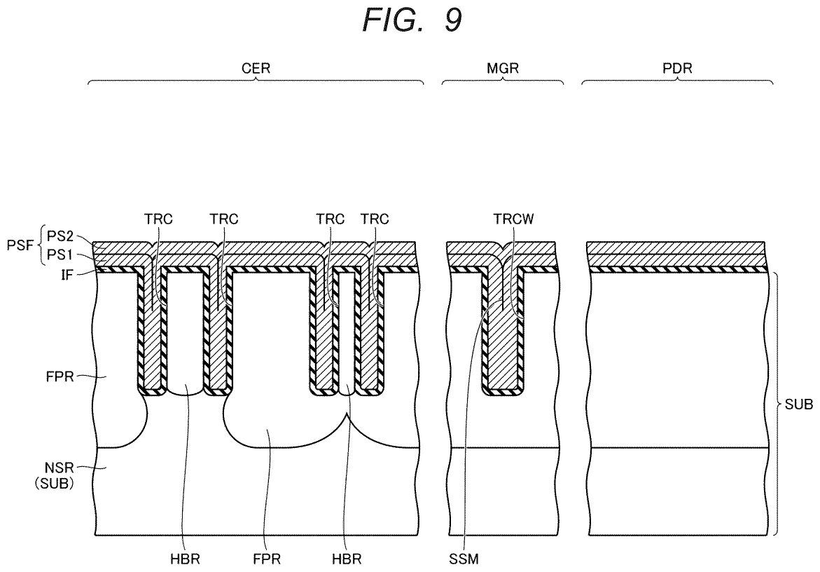

Next, a polysilicon film PSF (see FIG. 9) is formed to cover the semiconductor substrate SUB in a manner that fills the plurality of trenches TRC and TRCW. Here, the polysilicon film PSF is formed in two stages.

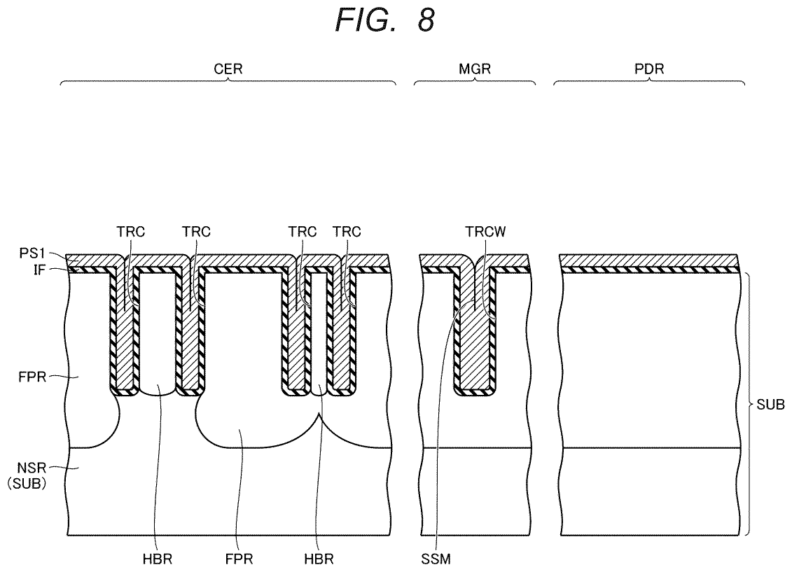

As shown in FIG. 8, first, the first layer of polysilicon film PS1 is formed. The semiconductor substrate SUB with the polysilicon film PS1 formed is removed from the deposition apparatus (not shown) and temporarily exposed to the atmosphere. At this time, the natural oxidation film SSM is formed on the surface of the polysilicon film PS1. Furthermore, by applying thermal oxidation treatment or oxygen plasma treatment (ashing treatment) to the polysilicon film PS1, the oxidation of the surface of the polysilicon film PS1 is promoted, making it easier to form the convex portion PRT (see FIG. 4) by the natural oxidation film SSM. Next, as shown in FIG. 9, the second layer of polysilicon film PS2 is formed to cover the polysilicon film PS1.

Thus, a polysilicon film PSF consisting of two layers, polysilicon film PS1 and polysilicon film PS2, is formed. At this time, the position of the upper surface of the polysilicon film PSF covering the relatively wide trench TRCW is lower than the position of the upper surface of the polysilicon film PSF covering the relatively narrow trench TRC.

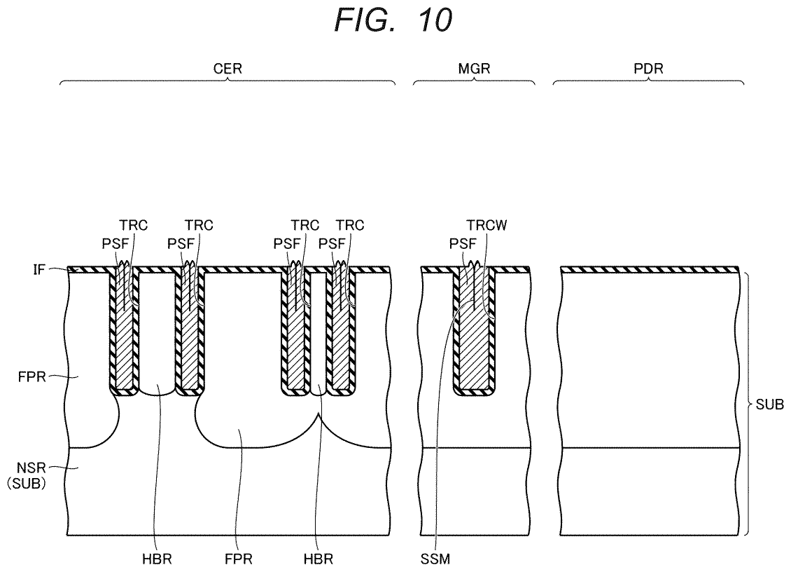

Next, as shown in FIG. 10, by performing etching on the entire surface of the polysilicon film PSF, the portion of the polysilicon film PSF located on the first main surface of the semiconductor substrate SUB is removed. At this time, the natural oxidation film SSM formed on the surface of the first layer of polysilicon film PS1 is exposed.

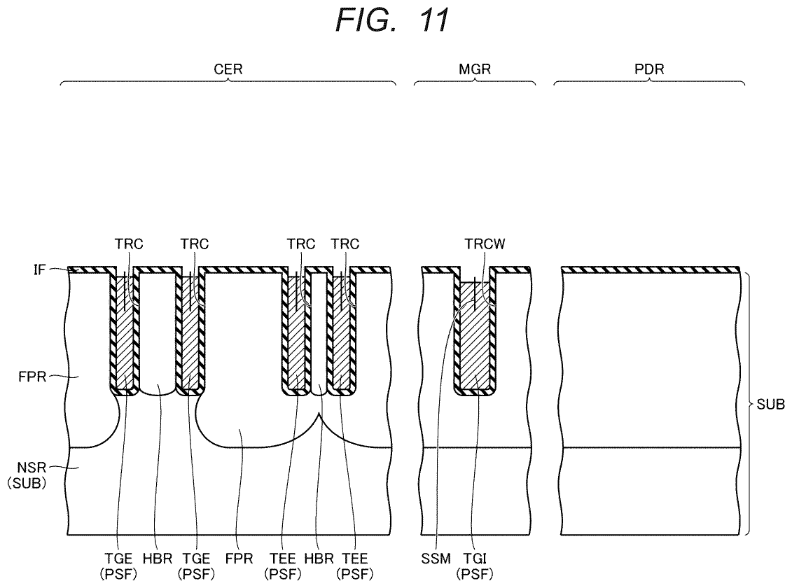

Next, as shown in FIG. 11, further over-etching is performed on the polysilicon film PSF. As a result, the upper surfaces of the polysilicon film PSF remaining in the plurality of trenches TRC and TRCW are positioned lower than the first main surface of the semiconductor substrate SUB. Additionally, the position of the upper surface of the polysilicon film PSF remaining in the trench TRCW is lower than the position of the upper surface of the polysilicon film PSF remaining in the trench TRC.

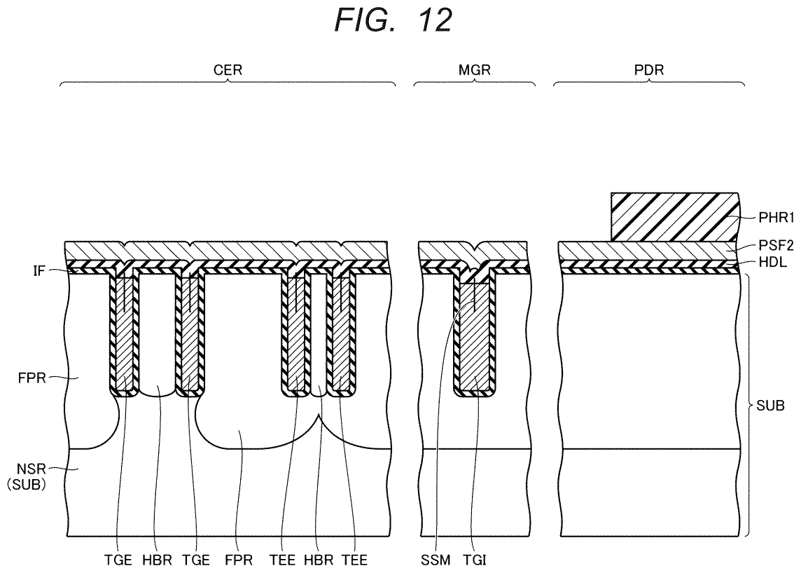

Next, as shown in FIG. 12, a silicon oxide film HDL is formed to cover the insulating film IF. Then, a polysilicon film PSF2 is formed to cover the silicon oxide film HDL. Next, by performing photolithography, a photoresist pattern PHR1 for patterning wiring is formed.

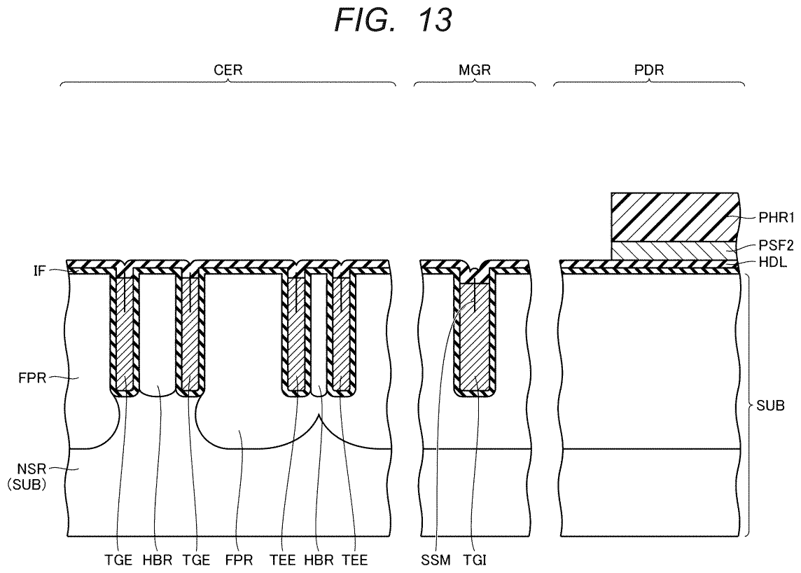

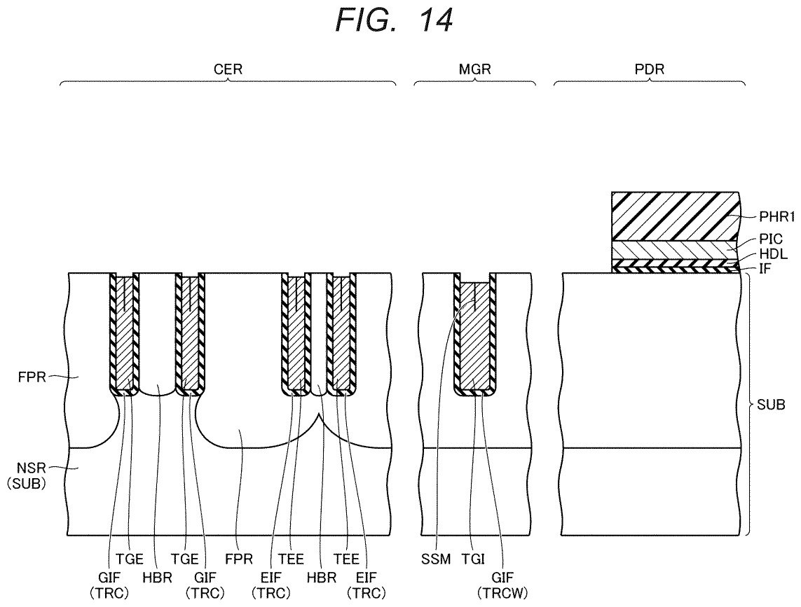

Next, as shown in FIG. 13, by using the photoresist pattern PHR1 as an etching mask, etching is performed on the polysilicon film PSF2 to form wiring PIC. Then, as shown in FIG. 14, by using the photoresist pattern PHR1 as an etching mask, etching is performed on the silicon oxide film HDL, and further etching is performed on the insulating film IF, thereby removing portions of the silicon oxide film HDL and the insulating film IF located on the first main surface of the semiconductor substrate SUB.

At this time, the natural oxidation film SSM protruding from the upper surface of the polysilicon film PSF is also removed along with the insulating film IF. Subsequently, the photoresist pattern PHR1 is removed. As a result, a trench emitter electrode TEE (third trench electrode, fourth trench electrode) is formed in the trench TRC with a trench insulating film EIF (insulating film IF) interposed. A trench gate electrode TGE (second trench electrode) is formed in the trench TRC with the insulating film GIF (insulating film IF) interposed. A trench gate lead-out electrode TGI (first trench electrode) is formed in the trench TRCW with the insulating film GIF (insulating film IF) interposed.

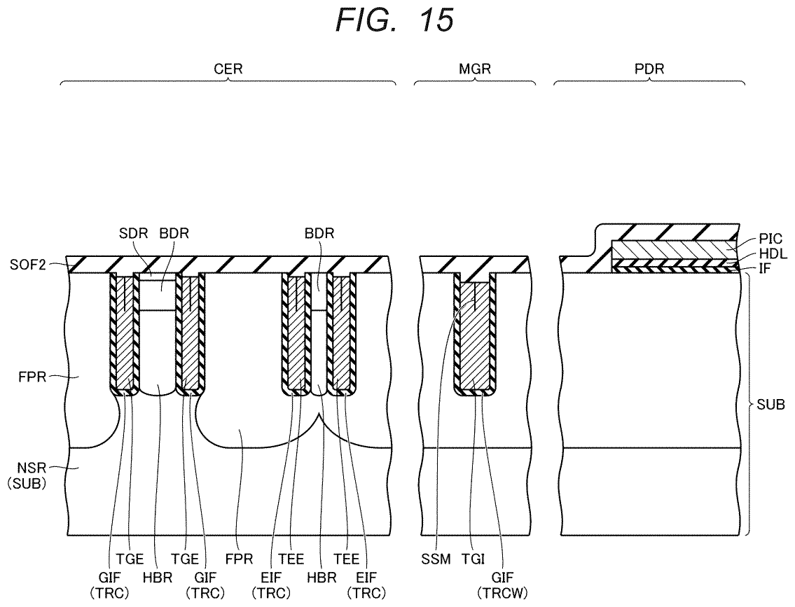

Next, as shown in FIG. 15, a silicon oxide film SOF2 is formed to cover the first main surface of the semiconductor substrate SUB. Then, by performing a predetermined photolithography process, a photoresist pattern (not shown) for forming a source diffusion layer and a base diffusion layer is formed. Next, using this photoresist pattern as an implantation mask, P-type impurities are implanted. Furthermore, N-type impurities are implanted. Subsequently, the photoresist pattern is removed.

As a result, a source diffusion layer SDR and a base diffusion layer BDR are formed in the region of the semiconductor substrate SUB located between one trench gate electrode TGE and another trench gate electrode TGE. A base diffusion layer BDR is formed in the region of the semiconductor substrate SUB located between one trench emitter electrode TEE and another trench emitter electrode TEE. The source diffusion layer SDR is formed to a predetermined depth from the first main surface. The base diffusion layer BDR is formed to a position deeper than the bottom of the base diffusion layer BDR. Subsequently, the silicon oxide film SOF2 is removed.

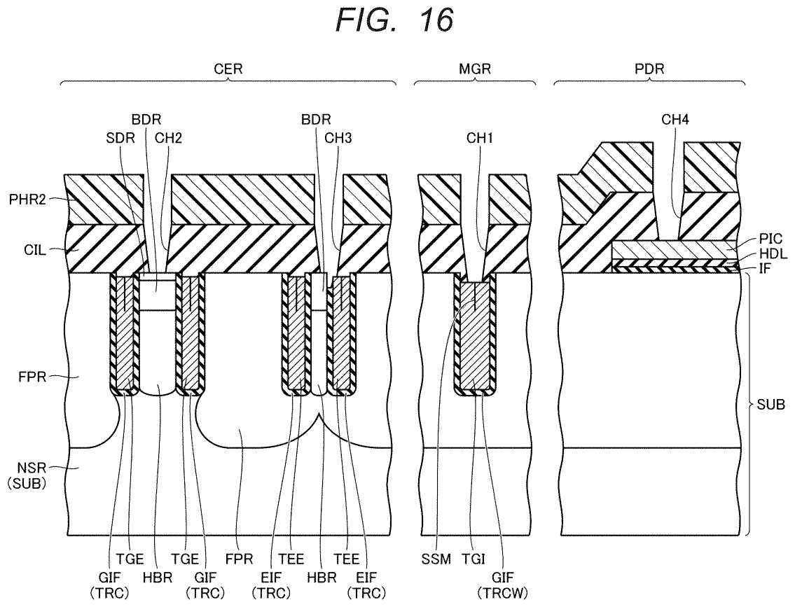

Next, the interlayer insulating film CIL is formed to cover the first main surface of the semiconductor substrate SUB (see FIG. 16). As the interlayer insulating film CIL, for example, a PSG film (Phospho Silicate Glass) is formed. Then, by performing a predetermined photolithography process, a photoresist pattern PHR2 for forming a plurality of contact openings in the interlayer insulating film CIL is formed (see FIG. 16).

Next, as shown in FIG. 16, by using the photoresist pattern PHR2 as an etching mask, etching (first etching process) is performed on the interlayer insulating film CIL. This etching process simultaneously forms the contact opening CH1 (first contact opening), the contact opening CH2, the contact opening CH3 (second contact opening) and the contact opening CH4. At this time, the contact opening CH3 is formed to span between the trench emitter electrode TEE and the region of the semiconductor substrate SUB.

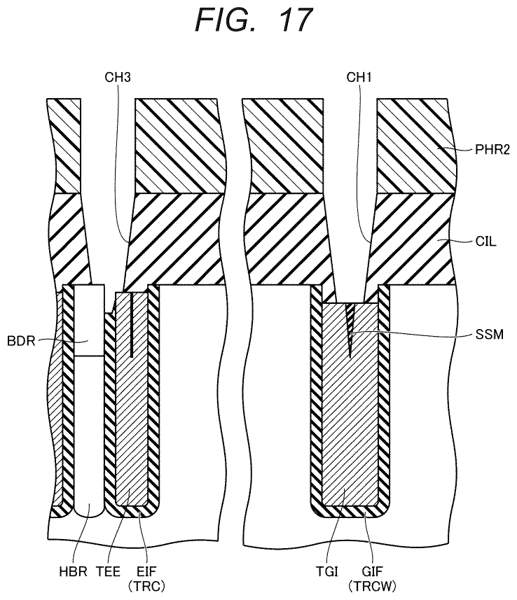

This etching process is performed using an etching gas (first gas) containing fluorocarbon (first fluorocarbon). In this etching process, the etching rate of the silicon oxide film becomes significantly larger than the etching rate of silicon. As a result, as shown in FIG. 17, in the contact opening CH3, the trench insulating film EIF located between the trench emitter electrode TEE and the region of the semiconductor substrate SUB recedes due to over-etching. At this time, a portion of the trench insulating film EIF remains as a residue on the sidewall surface of the trench emitter electrode TEE. On the other hand, in the contact opening CH1, the natural oxidation film SSM is thin, so it is hardly etched.

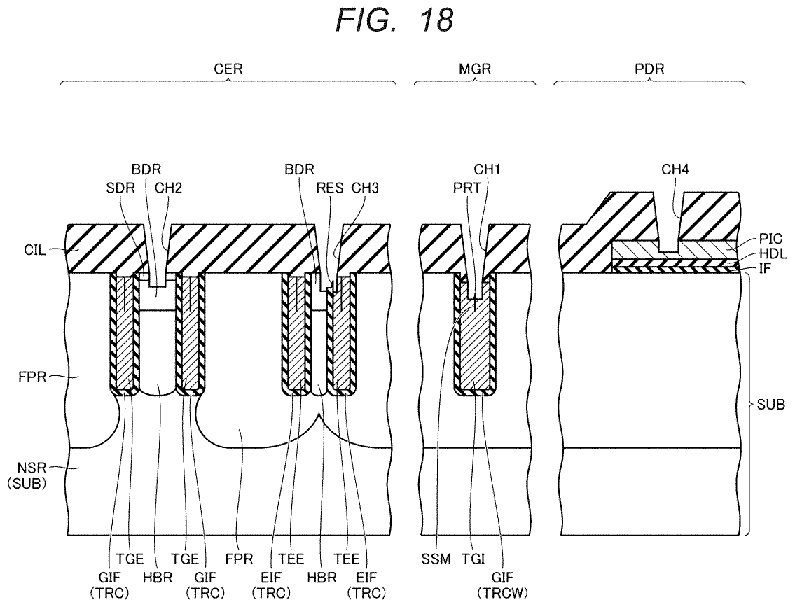

Next, as shown in FIG. 18, etching (second etching process) is performed on the exposed portions at a bottom of each of the contact openings CH1, CH2, and CH3. This etching process is performed using an etching gas (second gas) containing at least one of chlorine and hydrogen bromide. In this etching process, the etching rate of silicon becomes significantly larger than the etching rate of the silicon oxide film.

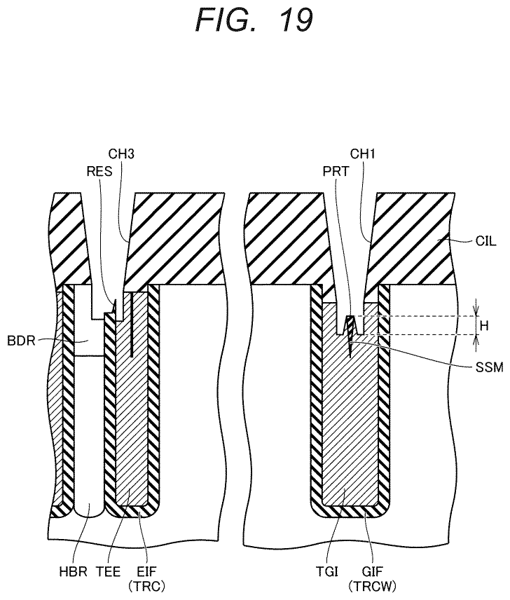

As a result, as shown in FIG. 19, in the contact opening CH1, the polysilicon film of the exposed trench gate lead-out electrode TGI is etched. At this time, a portion of the polysilicon film remains on the sidewall surface of the natural oxidation film SSM, and the remaining portion of the polysilicon film and the natural oxidation film SSM form the convex portion PRT. Furthermore, the height H of the convex portion PRT is ultimately etched to be at least 50 nm or more. The upper limit of the height H of the convex portion PRT is set to a height that can be well covered by the contact barrier metal film BME.

In the contact opening CH3, the polysilicon film of the exposed trench emitter electrode TEE and the portion of the semiconductor substrate SUB are etched. At this time, the residue RES of the trench insulating film EIF appears as a spike.

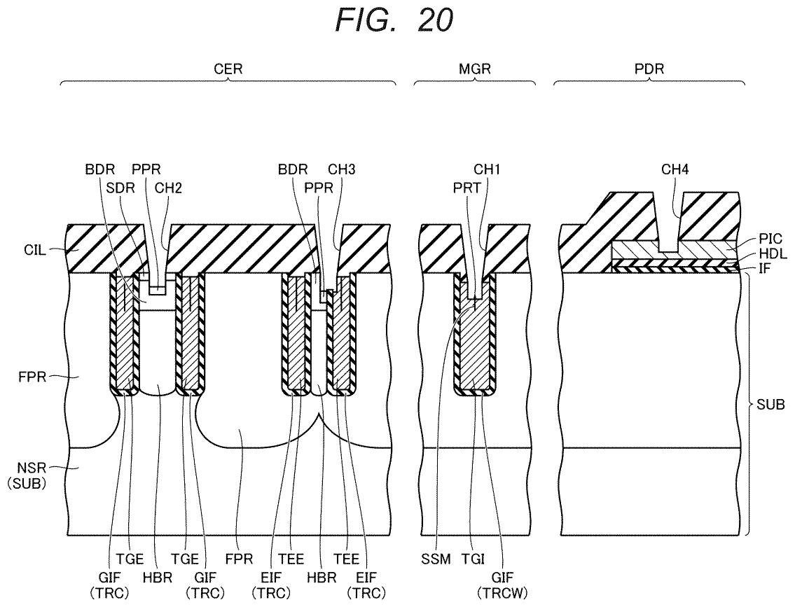

Next, as shown in FIG. 20, further etching (third etching process) is performed on the exposed portions at the bottom of each of the contact openings CH1, CH2, and CH3. This etching process is carried out using an etching gas (third gas) containing fluorocarbon (second fluorocarbon). In this etching process, the etching rate of the silicon oxide film becomes significantly larger than the etching rate of silicon.

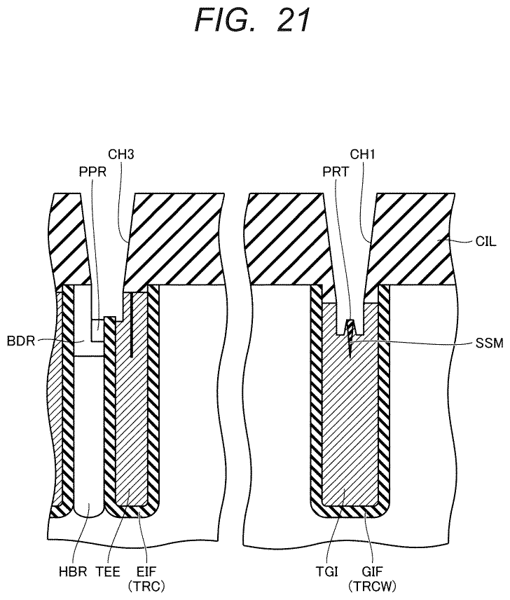

As a result, as shown in FIG. 21, the residue RES of the trench insulating film EIF is removed at the bottom of the contact opening CH3. At the bottom of the contact opening CH1, the natural oxidation film SSM is not completely removed due to the formation of a polysilicon film on the sidewall surface of the protruding natural oxidation film SSM, leaving it as the convex portion PRT.

Next, P+ type impurities are implanted through the contact openings CH1 to CH3. As a result, a P+ layer PPR having a higher impurity concentration than the base diffusion layer BDR is formed in the P-type base diffusion layer BDR exposed at the bottom of the contact opening CH3. Similarly, a P+ layer PPR having a higher impurity concentration than the base diffusion layer BDR is formed in the P-type base diffusion layer BDR exposed at the bottom of the contact opening CH2.

At this time, P+ type impurities are also implanted into the side of the exposed N-type source diffusion layer SDR at the bottom of the contact opening CH2. Therefore, the N-type impurities of the source diffusion layer SDR, which will contact the gate contact member GDC, are neutralized by the P+ type impurities, potentially increasing the contact resistance between the source diffusion layer SDR and the gate contact member GDC.

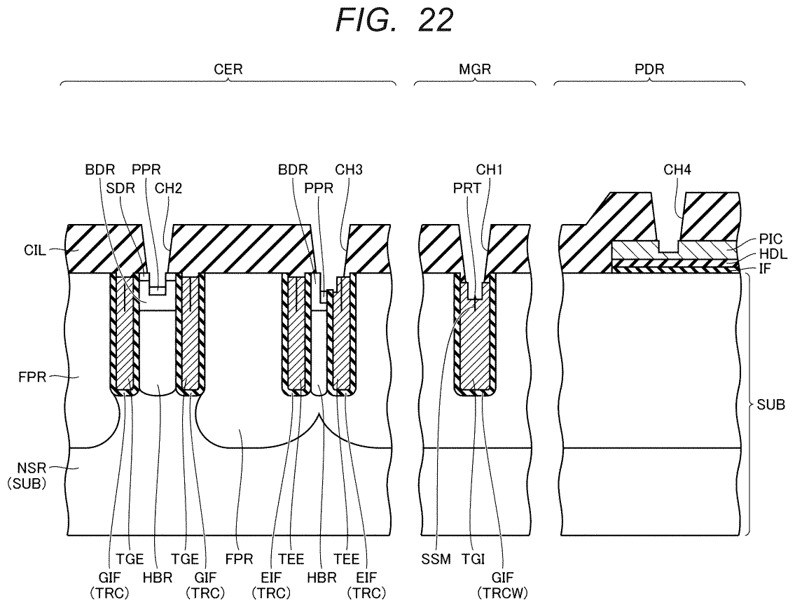

Next, as shown in FIG. 22, an opening width of the contact opening CH2 and others is widened by performing a wet etching process on the interlayer insulating film CIL. By widening the opening width of the contact opening CH2, the upper surface of the source diffusion layer SDR, which has not been implanted with P+ type impurities, is exposed. This reduces the contact resistance between the gate contact member GDC and the source diffusion layer SDR. At this time, the convex portion PRT exposed at the bottom of the contact opening CH1 is not removed because the sidewall surface of the natural oxidation film SSM is covered by the polysilicon film (see FIG. 21).

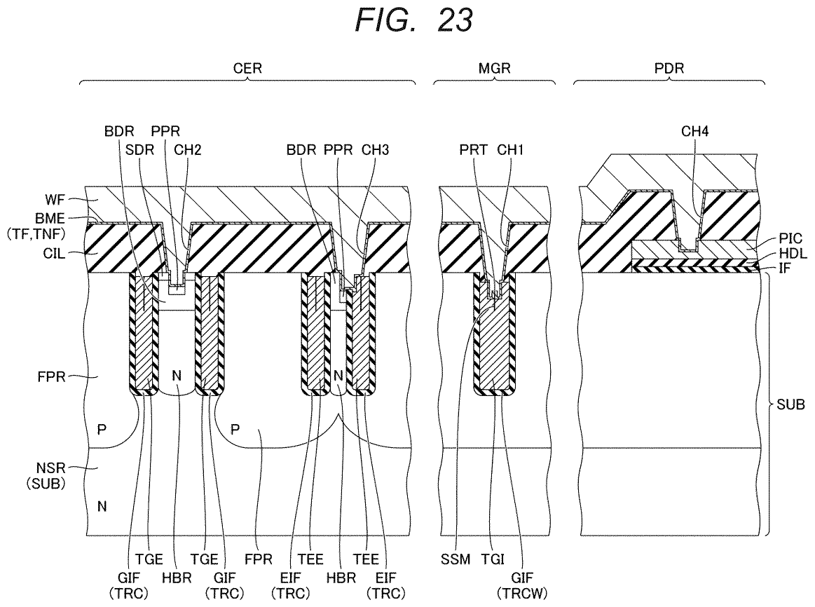

Next, as shown in FIG. 23, the contact barrier metal film BME is formed to cover the interlayer insulating film CIL, including the inner wall surfaces of the contact openings CH1 to CH3. As the contact barrier metal film BME, a laminated film of a titanium nitride film TNF (TiN: upper layer) and a titanium film TF (Ti: lower layer) is formed. Next, a tungsten film WF is formed to cover the contact barrier metal film BME. Then, by performing a full-surface etch-back process on the tungsten film WF and others, the tungsten film WF and the contact barrier metal film BME located on the upper surface of the interlayer insulating film CIL are removed.

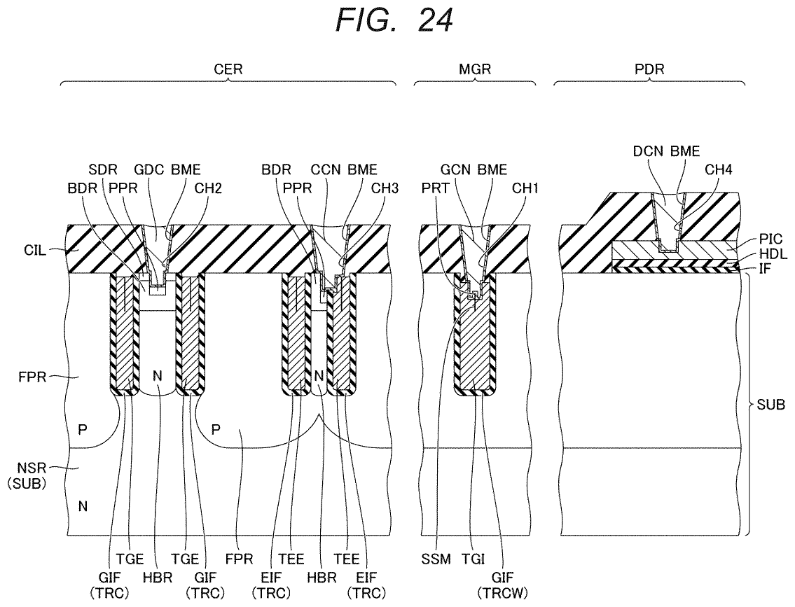

As a result, as shown in FIG. 24, the gate lead-out contact member GCN is formed within the contact opening CH1. Within the contact opening CH1, the contact barrier metal film BME is formed to cover the convex portion PRT. The gate lead-out contact member GCN is formed by interposing the contact barrier metal film BME that covers the convex portion PRT. The gate contact member GDC is formed within the contact opening CH2. The shared contact member CCN is formed within the contact opening CH3.

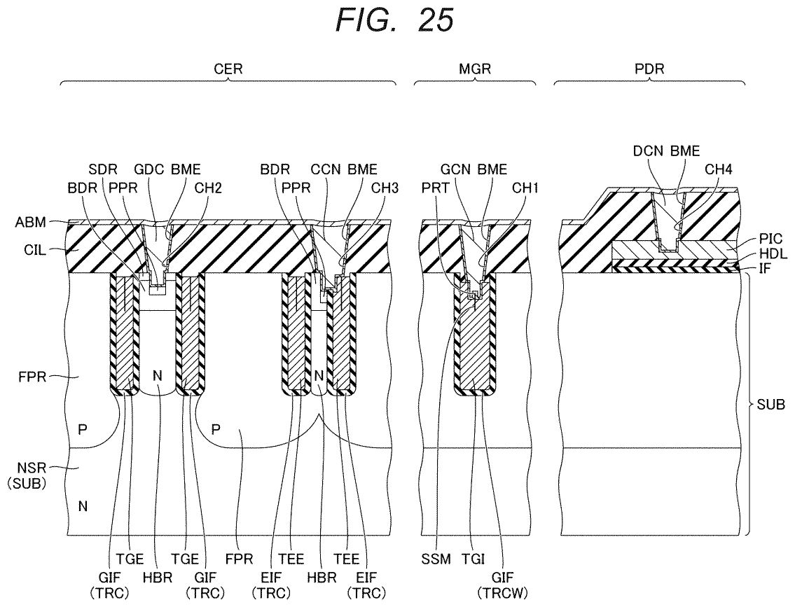

Next, as shown in FIG. 25, the interlayer barrier metal film ABM is formed to cover the interlayer insulating film CIL. As the interlayer barrier metal film ABM, for example, a titanium-tungsten film (TiW) is formed. Next, to improve the adhesion between the interlayer barrier metal film ABM and the interlayer insulating film CIL, heat treatment is performed on the interlayer barrier metal film ABM at a temperature of 650 degree Celsius or higher, for example, by lamp annealing.

Thereafter, an aluminum film (not shown) is formed to cover the interlayer barrier metal film ABM, and by patterning the aluminum film, an emitter electrode MEE, a gate lead-out wiring MGI, and a gate electrode MGE, etc., are formed (see FIG. 3, etc.). Next, an N-type buffer layer NBR and a P-type collector diffusion layer CDR are formed on the second main surface side of the semiconductor substrate SUB. Furthermore, a collector electrode BEL (back electrode) is formed, completing the semiconductor device SED shown in FIGS. 1 to 3.

Next, the operation of the above-described semiconductor device SED will be explained. First, when turning on the trench insulated gate bipolar transistor, a voltage equal to or greater than the threshold voltage is applied to the gate electrode MGE. As a result, electrons are injected from the source diffusion layer SDR through the channel into the N-type region NSR (drift layer) in the semiconductor substrate SUB, and the PN junction between the N-type region NSR and the collector diffusion layer CDR becomes forward-biased, allowing holes to be injected from the collector diffusion layer CDR into the N-type region NSR.

The injected holes are prevented from escaping to the source diffusion layer SDR (emitter) side by the P-type floating diffusion layer FPR, and holes accumulate in the N-type region NSR and the floating diffusion layer FPR, increasing the hole concentration. As the hole concentration in the N-type region NSR and others increases, the injection of electrons from the source diffusion layer SDR is promoted, and the electron concentration also increases. Thus, as the carrier concentration in the N-type region NSR and others increases, conductivity modulation occurs, and the device turns on.

Next, when turning off the trench insulated gate bipolar transistor, a voltage lower than the threshold voltage is applied to the gate electrode MGE. As a result, the channel disappears. The carriers (holes) accumulated in the N-type region NSR and others are discharged to the emitter electrode MEE by the parasitic P-channel MOSFET (floating diffusion layer FPR, trench emitter electrode TEE at emitter potential, base diffusion layer BDR, etc.) formed on the trench emitter electrode TEE side, turning the device off.

In the above-described semiconductor device SED, when heat treatment (temperature 650 degree Celsius or higher) is applied to the interlayer barrier metal film ABM, it was confirmed by the inventors that voids occur in the contact barrier metal film BME due to the partial silicidation of the contact barrier metal film BME, particularly on the trench gate lead-out electrode TGI.

The contact barrier metal film BME is formed as a laminated film of a titanium film TF (lower layer) and a titanium nitride film TNF (upper layer). Particularly, at the bottom of the contact opening CH1, the titanium film TF is formed to contact the trench gate lead-out electrode TGI. The trench gate lead-out electrode TGI is formed from a polysilicon film PSF (see FIG. 9). Therefore, during the heat treatment of the interlayer barrier metal film ABM, titanium silicide TSF (TiSi) is formed by the reaction between the titanium film TF and silicon (Si).

The inventors considered that the occurrence of voids might be due to the formation of titanium silicide in part of the contact barrier metal film BME during heat treatment and evaluated the film stress through simulation.

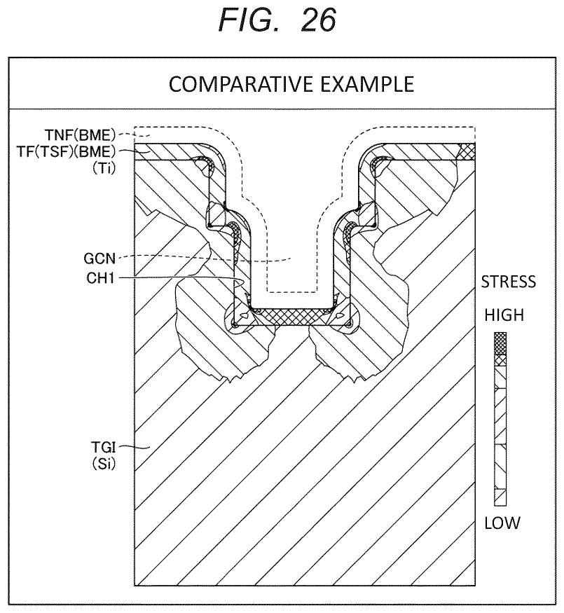

FIG. 26 shows the simulation results for a comparative example. In the comparative example, the portion of the trench gate lead-out electrode TGI located at the bottom of the contact opening CH1 is a flat surface. Also, the titanium film TF of the contact barrier metal film BME is formed to contact the trench gate lead-out electrode TGI (polysilicon film PSF).

Due to the heat treatment, the titanium film TF is silicided to form titanium silicide TSF, resulting in film stress in the titanium film TF. Particularly, it was found that film stress is concentrated on the titanium nitride film TNF side in the portion of the titanium film TF (including titanium silicide TSF) located at the bottom of the contact opening CH1. The inventors considered that the film stress concentrated in this portion causes voids to form between the titanium film and the titanium nitride film TNF.

Therefore, the inventors evaluated a structure to alleviate the film stress occurring on the titanium nitride film TNF side in the portion of the titanium film TF (including titanium silicide) located at the bottom of the contact opening CH1. As a result, it was found that forming the convex portion PRT with a predetermined height in the portion of the trench gate lead-out electrode TGI located at the bottom of the contact opening CH1 can alleviate the film stress occurring on the titanium nitride film TNF side. Specifically, it was found that if the height H of the convex portion PRT is at least 50 nm or more, the film stress can be alleviated.

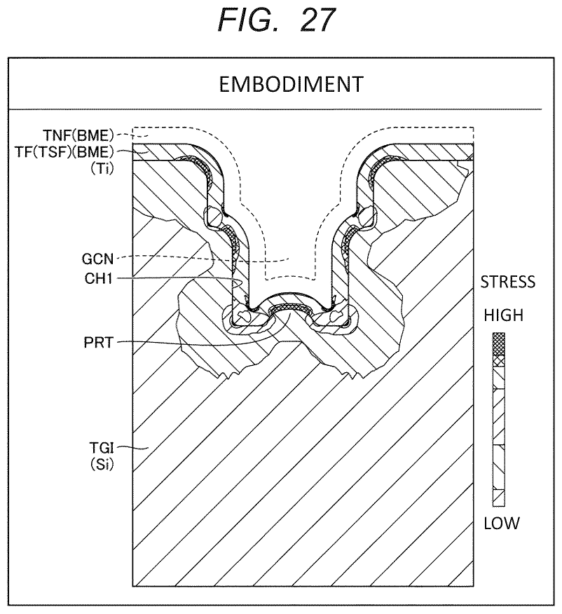

FIG. 27 shows the simulation results for the embodiment. In the embodiment, the convex portion PRT is formed in the portion of the trench gate lead-out electrode TGI located at the bottom of the contact opening CH1. Also, the titanium film TF of the contact barrier metal film BME is formed to contact the trench gate lead-out electrode TGI (polysilicon film PSF) so as to cover the convex portion PRT.

As shown in FIG. 27, in the titanium film TF formed to cover the convex portion PRT, film stress is concentrated on the trench gate lead-out electrode TGI side at the corner of the bottom surface of the contact opening CH1, and it was found that the film stress occurring on the titanium nitride film TNF side in the portion of the titanium film TF covering the convex portion PRT is reduced.

Based on this evaluation result, the inventors first formed the convex portion PRT using the natural oxidation film SSM formed during the creation of the trench gate lead-out electrode TGI and others. By forming the contact barrier metal film BME to cover the convex portion PRT, it was confirmed that the formation of voids between the titanium film TF (including titanium silicide) and the titanium nitride film TNF can be suppressed.

With the suppression of void formation, the leakage current (ICES) can be reduced. The leakage current (ICES) refers to the current that flows between the collector electrode BEL and the emitter electrode MEE when a predetermined voltage is applied between the collector electrode BEL and the emitter electrode MEE while the gate electrode MGE and the emitter electrode MEE are short-circuited.

Furthermore, in the structure where the trench gate lead-out electrode TGI is formed within the contact opening CH1, suppressing the formation of voids can reduce the current density flowing through the gate lead-out contact member GCN.

In the aforementioned semiconductor device SED, a laminated film of a titanium film Ti and a titanium nitride film TNF was cited as an example of the contact barrier metal film BME. The contact barrier metal film BME may also be a titanium tungsten film (TiW). In this case, tungsten silicide is formed on the titanium tungsten film through heat treatment. Alternatively, the contact barrier metal film BME may be a laminated film of a tungsten film (W) and a tungsten nitride film (WN). In this case, tungsten silicide is formed on the tungsten film through heat treatment.

Additionally, a titanium film may be used. In this case, annealing in a nitrogen atmosphere forms titanium nitride (TiN) and titanium silicide (TiSi). A tungsten film (W) may also be used. In this case, annealing in a nitrogen atmosphere forms tungsten nitride (WN) and tungsten silicide (WSi).

Moreover, a tungsten film WF was formed as the gate lead-out contact member GCN and others. Alternatively, a tungsten nitride film (WN) may be applied.

### Second Embodiment

Here, an example of a GE-type semiconductor device is described. First, the cell region CER is explained.

### Cell Region CER

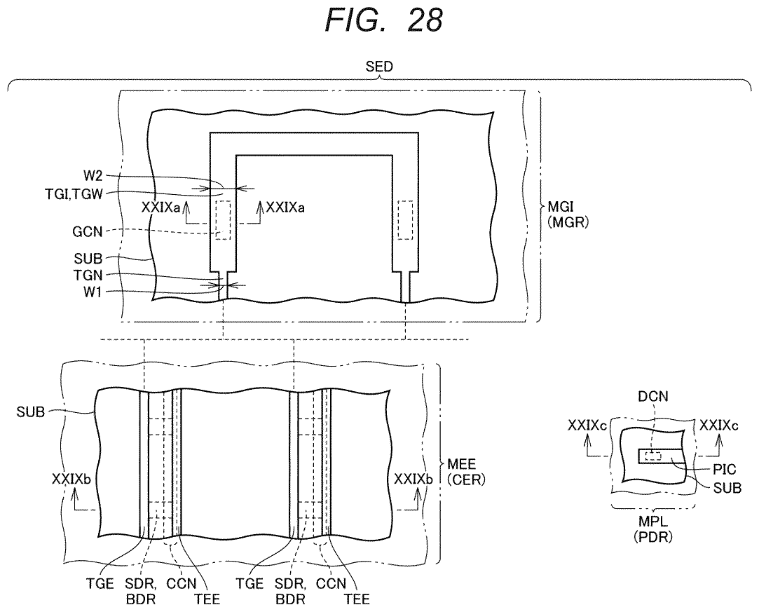

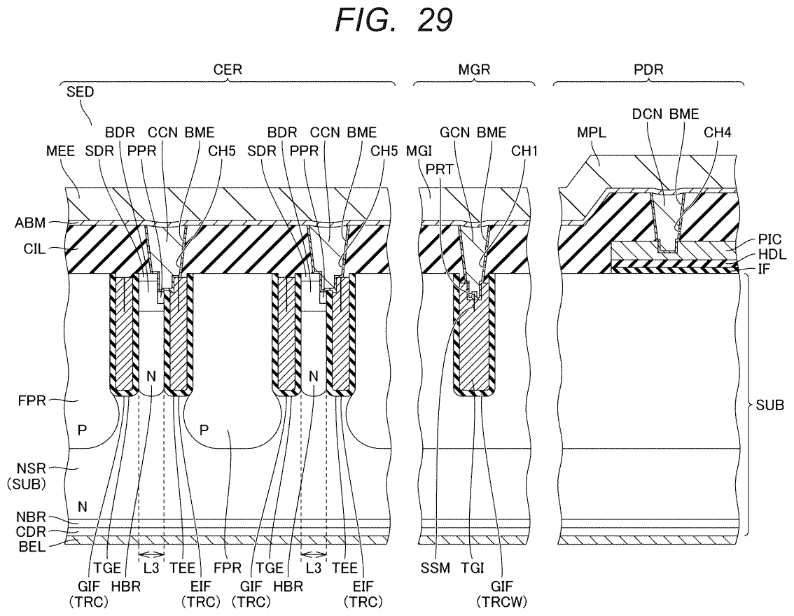

As shown in FIGS. 28 and 29, the trench gate electrode TGE (second trench electrode) and the trench emitter electrode TEE (third trench electrode) are arranged with a spacing L3 in one direction. The trench gate electrode TGE and the trench emitter electrode TEE extend in another direction that intersects the first direction.

In a region of a semiconductor substrate SUB located between the trench gate electrode TGE and the trench emitter electrode TEE, an N+ type source diffusion layer SDR is formed from a first main surface to a predetermined depth. From the bottom of the source diffusion layer SDR to a further predetermined depth, a P-type base diffusion layer BDR is formed. In the base diffusion layer BDR, a P+ layer PPR with a higher concentration of P-type impurities is formed.

To cover the trench gate electrode TGE, trench emitter electrode TEE, and others, an interlayer insulating film CIL is formed on the semiconductor substrate SUB. A contact opening CH5 is formed to penetrate the interlayer insulating film CIL. Within the contact opening CH5, a shared contact member CCN (second contact member) is formed with a contact barrier metal film BME interposed.

The structure of the gate wiring lead-out region MGR, where a trench gate lead-out electrode TGI (first trench electrode) with a convex portion PRT is formed, and the structure of the peripheral element region PDR, etc., are similar to those shown in FIGS. 2, 3, and 4. Therefore, the same reference numerals are used for the same members, and their descriptions are not repeated unless necessary.

### Manufacturing Method

Next, an example of the manufacturing method for the aforementioned semiconductor device SED is described. The arrangement pattern of the trench gate electrode TGE (trench TRC) and the trench emitter electrode TEE (trench TRC) differs from the arrangement pattern of the trench gate electrode TGE and the trench emitter electrode TEE in the aforementioned semiconductor device SED, but the semiconductor device SED is manufactured by substantially the same manufacturing method as the aforementioned semiconductor device SED.

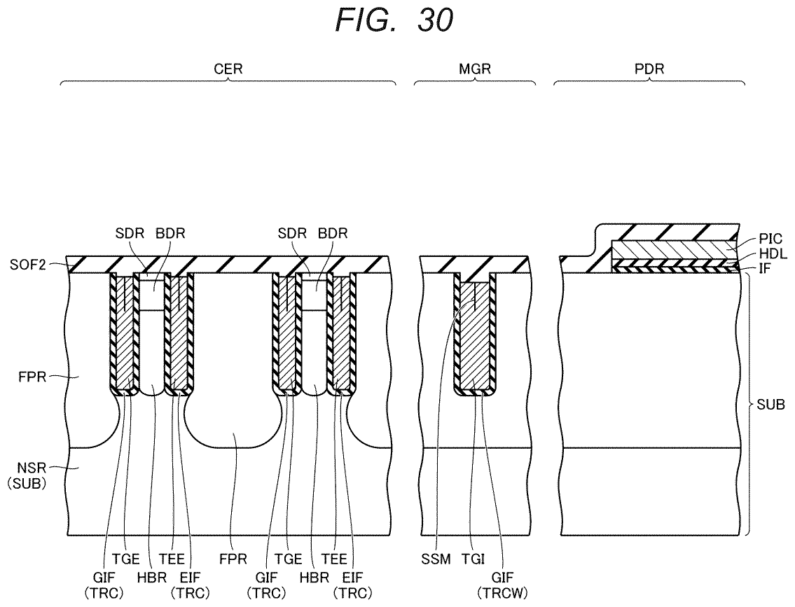

After going through substantially the same processes as shown in FIGS. 5 to 14, as shown in FIG. 30, a silicon oxide film SOF2 is formed to cover the first main surface of the semiconductor substrate SUB. Next, by performing a predetermined photolithography process, a photoresist pattern (not shown) for forming the base diffusion layer BDR is formed.

Next, using the photoresist pattern as an implantation mask, P-type impurities are implanted to form the base diffusion layer BDR. Also, by implanting N-type impurities, the source diffusion layer SDR is formed. After that, the photoresist pattern is removed. Additionally, the silicon oxide film SOF2 is removed. This forms the base diffusion layer BDR and the source diffusion layer SDR in the region of the semiconductor substrate SUB located between the adjacent trench gate electrode TGE and trench emitter electrode TEE.

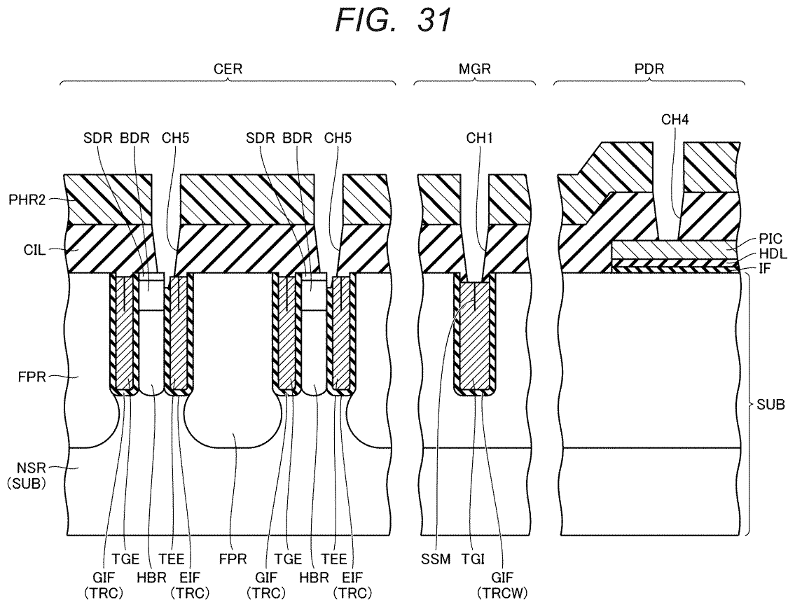

Next, the interlayer insulating film CIL (see FIG. 31) is formed to cover the first main surface of the semiconductor substrate SUB. Then, by performing a predetermined photolithography process, a photoresist pattern PHR2 (see FIG. 31) for forming a plurality of contact openings in the interlayer insulating film CIL is formed. Next, as shown in FIG. 31, using the photoresist pattern PHR2 as an etching mask, an etching process (first etching process) is performed on the interlayer insulating film CIL.

This etching process simultaneously forms the contact opening CH1 (first contact opening), the contact opening CH5 (second contact opening), and the contact opening CH4. At this time, the contact opening CH5 is formed to span between the trench emitter electrode TEE and the region of the semiconductor substrate SUB.

Also, this etching process is performed using an etching gas (first gas) containing fluorocarbon (first fluorocarbon) as described above. At this time, particularly in the contact opening CH1, because the contact opening CH1 is narrow, a natural oxidation film SSM is hardly etched.

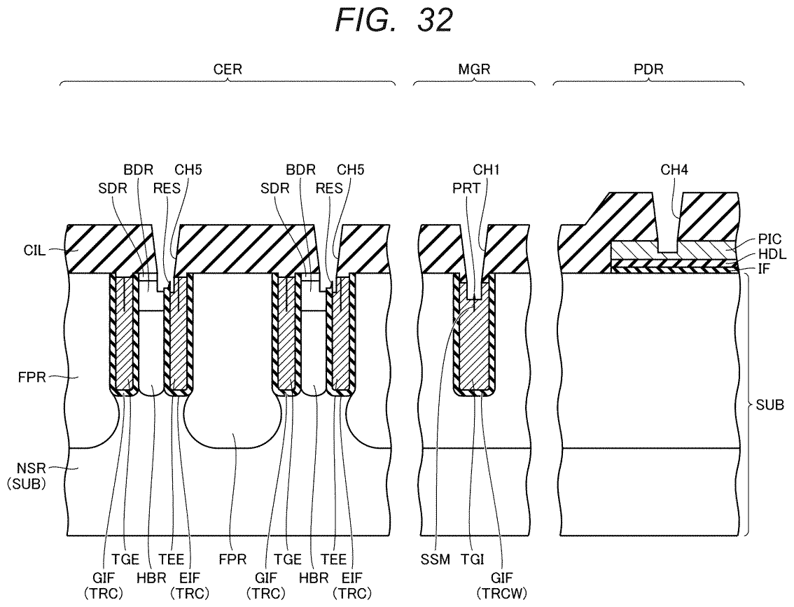

Next, as shown in FIG. 32, an etching process (second etching process) is performed on the exposed portions at the bottom of each of the contact openings CH1 and CH5. This etching process is performed using an etching gas (second gas) containing at least one of chlorine and hydrogen bromide as described above.

This etching process etches the polysilicon film of the exposed trench gate lead-out electrode TGI in the contact opening CH1. At this time, portions of the polysilicon film remain on the sidewall surface of the natural oxidation film SSM (see FIG. 19). Also, in the contact opening CH5, the polysilicon film of the exposed trench emitter electrode TEE and the portion of the semiconductor substrate SUB are etched. Furthermore, a residue RES of a trench insulating film EIF appears as a spike (see FIG. 19).

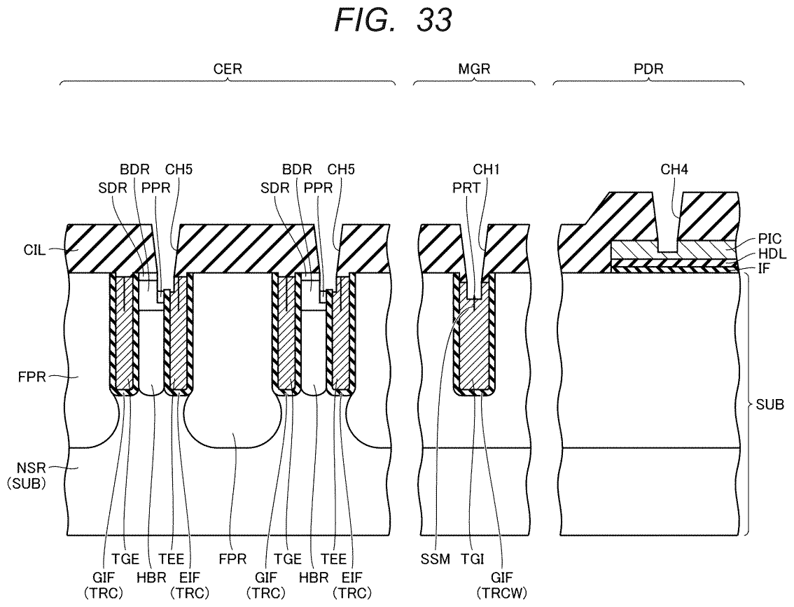

Next, as shown in FIG. 33, a further etching process (third etching process) is performed on the exposed portions at the bottom of each of the contact openings CH1 and CH5. This etching process is performed using an etching gas (third gas) containing fluorocarbon (second fluorocarbon) as described above.

This etching process removes the residue RES of the trench insulating film EIF at a bottom of the contact opening CH5. At the bottom of the contact opening CH1, because the polysilicon film is formed on the sidewall surface of the protruding natural oxidation film SSM, the natural oxidation film SSM is not completely removed and remains as the convex portion PRT.

Next, P+ type impurities are implanted through the contact opening CH5 and others. This forms a P+ layer PPR with a higher impurity concentration than the impurity concentration of the base diffusion layer BDR in the P-type base diffusion layer BDR exposed at the bottom of the contact opening CH3.

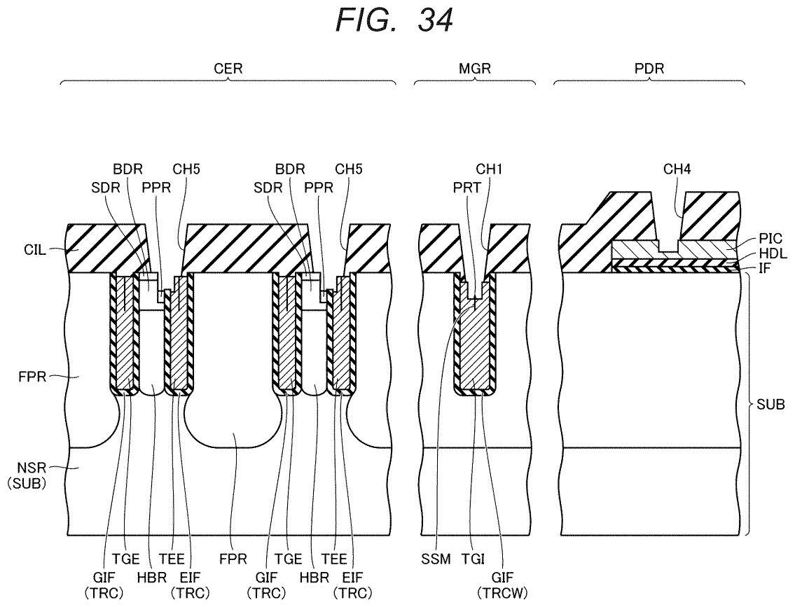

Next, as shown in FIG. 34, by performing a wet etching process on the interlayer insulating film CIL, an opening width of the contact opening CH5 and others is widened. This exposes the upper surface of the source diffusion layer SDR, which has not been implanted with P+ type impurities. At this time, in the convex portion PRT exposed at a bottom of the contact opening CH1, because the sidewall surface of the natural oxidation film SSM is covered with a polysilicon film, the convex portion PRT is not removed (see FIG. 21).

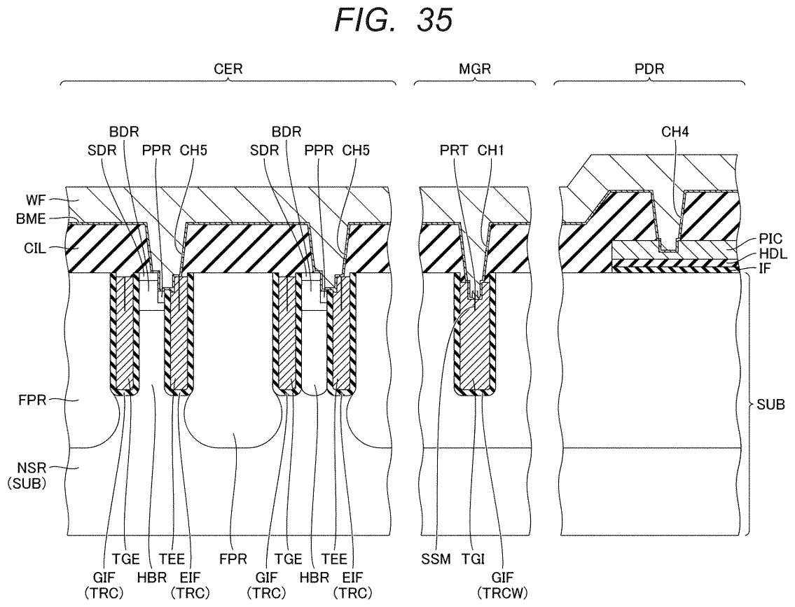

Next, a process similar to the one shown in FIG. 23 is performed. This forms the contact barrier metal film BME to cover the interlayer insulating film CIL, including the inner wall surfaces of the contact opening CH1 and the contact opening CH5, as shown in FIG. 35. Next, a tungsten film WF is formed to cover the contact barrier metal film BME.

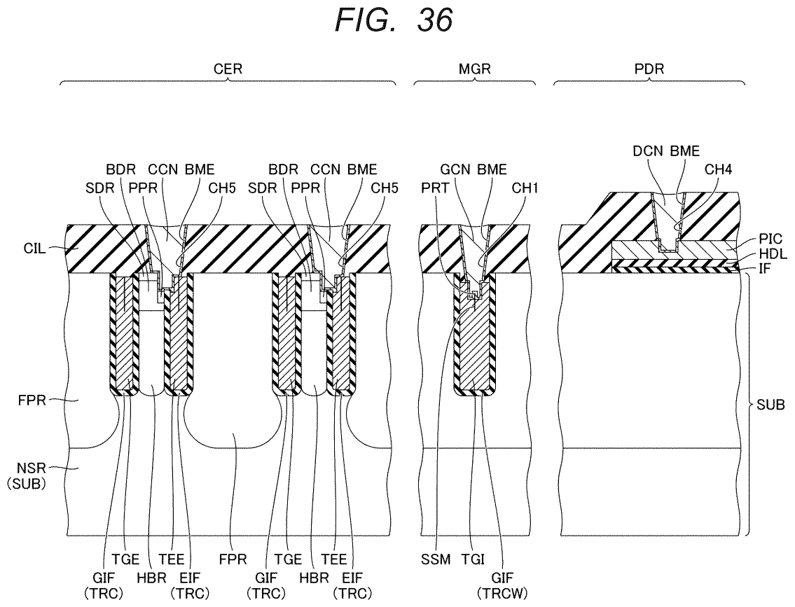

Next, a process similar to the one shown in FIG. 24 is performed. This forms a gate lead-out contact member GCN within the contact opening CH1, as shown in FIG. 36. Within the contact opening CH1, the contact barrier metal film BME is formed to cover the convex portion PRT. The gate lead-out contact member GCN is formed with the contact barrier metal film BME covering the convex portion PRT interposed. The shared contact member CCN is formed within the contact opening CH5.

Next, a process similar to the one shown in FIG. 25 is performed. This forms an interlayer barrier metal film ABM to cover the interlayer insulating film CIL. Next, to improve the adhesion between the interlayer barrier metal film ABM and the interlayer insulating film CIL, for example, by lamp annealing, a heat treatment is performed on the interlayer barrier metal film ABM at a temperature of 650 degree Celsius or higher.

After that, an emitter electrode MEE, gate lead-out wiring MGI, and gate electrode MGE, etc., are formed on the interlayer barrier metal film ABM (see FIG. 29, etc.). Also, on a second main surface side of the semiconductor substrate SUB, an N-type buffer layer NBR, a P-type collector diffusion layer CDR, and a collector electrode BEL (back electrode) are formed, completing the semiconductor device SED shown in FIGS. 28 and 29.

In the aforementioned semiconductor device SED, the convex portion PRT is formed on the trench gate lead-out electrode TGI. The contact barrier metal film BME is formed to cover the convex portion PRT. As a result, as described in the first embodiment, in the titanium film TF, film stress is concentrated on the trench gate lead-out electrode TGI side at the corner of the bottom surface of the contact opening CH1, and in the portion of the titanium film TF covering the convex portion PRT, the film stress occurring on the titanium nitride film TNF side is reduced.

As a result, the occurrence of voids between the titanium film TF (including titanium silicide) and the titanium nitride film TNF can be suppressed. By suppressing the occurrence of voids, leakage current (ICES) can be reduced. Additionally, the current density flowing through the gate lead-out contact member GCN can be reduced.

### Third Embodiment

Here, an example of an EGE-type semiconductor device is described. The EGE-type semiconductor device SED is used for applications requiring high-speed performance. The cell region CER is explained.

### Cell Region CER

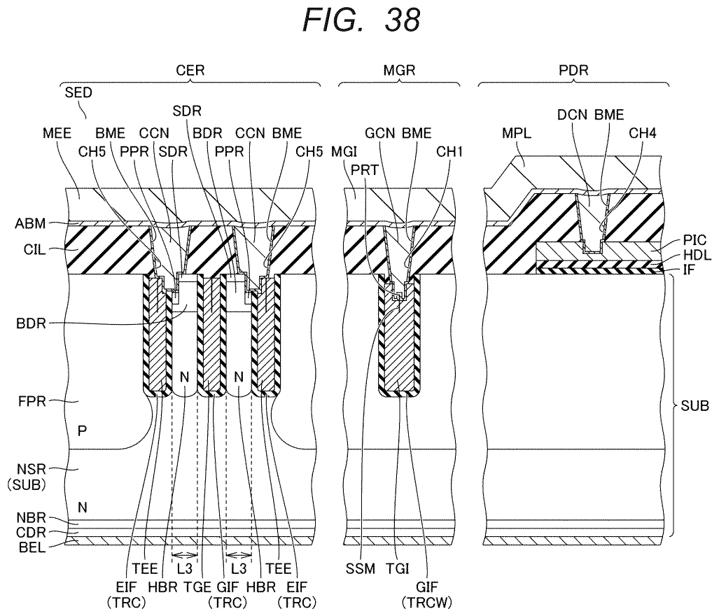

As shown in FIG. 38, in the cell region CER, a trench emitter electrode TEE (third trench electrode), a trench gate electrode TGE (second trench electrode), and another trench emitter electrode TEE are formed.

The trench emitter electrode TEE, trench gate electrode TGE, and another trench emitter electrode TEE are formed with a spacing L3 between them, with the trench gate electrode TGE positioned between the trench emitter electrode TEE and the other trench emitter electrode TEE.

Regarding the structure of the gate wiring lead-out region MGR, which has a trench gate lead-out electrode TGI (first trench electrode) with a convex portion PRT, and the structure of the peripheral element region PDR, etc., they are similar to the structures shown in FIGS. 2, 3, and 4. Therefore, the same reference numerals are used for the same components, and their descriptions will not be repeated unless necessary.

Next, an example of the manufacturing method for the aforementioned semiconductor device SED will be described. The arrangement pattern of the trench gate electrode TGE (trench TRC) and the trench emitter electrode TEE (trench TRC) differs only from the arrangement pattern of the trench gate electrode TGE and trench emitter electrode TEE in the semiconductor device SED shown in FIG. 3, etc. The semiconductor device SED can be manufactured by substantially the same manufacturing method as described in the first embodiment.

In the aforementioned semiconductor device SED, the convex portion PRT is formed on the trench gate lead-out electrode TGI. A contact barrier metal film BME is formed to cover the convex portion PRT. As a result, as described in the first embodiment, in the titanium film TF, film stress concentrates on the trench gate lead-out electrode TGI side at the corner of a bottom of a contact opening CH1, and in the portion of the titanium film TF covering the convex portion PRT, the film stress occurring on the titanium nitride film TNF side is reduced.

Consequently, the occurrence of voids between the titanium film TF (including titanium silicide TSF) and the titanium nitride film TNF can be suppressed. By suppressing the occurrence of voids, the leakage current (ICES) can be reduced. Additionally, the current density flowing through a gate lead-out contact member GCN can be reduced.

The semiconductor device and its manufacturing method described in each embodiment can be variously combined as needed.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a semiconductor substrate having a first main surface and a second main surface opposite to the first main surface;
a plurality of trenches formed in the semiconductor substrate from the first main surface towards the second main surface;
a plurality of trench electrodes formed in each of the plurality of trenches;
an interlayer insulating film formed on the first main surface having a plurality of contact openings such that the plurality of contact openings reaches each of the plurality of trench electrodes;
a plurality of contact members formed in each of the plurality of contact openings via a contact barrier metal film, wherein
the plurality of trenches includes a first trench,
the plurality of trench electrodes includes a first trench electrode formed in the first trench,
the plurality of contact openings includes a first contact opening reaching the first trench electrode,
the plurality of contact members includes a first contact member formed in the first contact opening and contacting with the first trench electrode,
a convex portion of the first trench electrode is formed at a bottom of the first contact opening such that the convex portion protrudes toward the first main surface, and
the convex portion is contacted with the first contact member via the contact barrier metal film.

2. The semiconductor device according to claim 1, wherein
a height of the convex portion is at least 50 nm.

3. The semiconductor device according to claim 1, wherein
the convex portion includes an oxidation film.

4. The semiconductor device according to claim 1, wherein
the contact barrier metal film includes a metal that is able to.

5. The semiconductor device according to claim 1, wherein
the contact barrier metal film includes laminated a titanium film and a titanium nitride film.

6. The semiconductor device according to claim 1, wherein
the first contact member includes at least one of tungsten or tungsten nitride.

7. The semiconductor device according to claim 1, wherein
the plurality of trenches includes a second trench,
the plurality of trench electrodes includes a second trench electrode formed in the second trench and electrically connected to the first trench electrode,
the first trench has a first width and the second trench has a second width, and
and the first width is wider than the second width.

8. The semiconductor device according to claim 7, wherein
the plurality of trenches includes a third trench,
the plurality of trench electrodes includes a third trench electrode formed in the third trench via a trench insulating film,
the plurality of contact openings includes a second contact opening such that the second contact opening straddles between the third trench electrode, the trench insulating film and a part of the semiconductor substrate, in plan view, and
the plurality of contact members includes a second contact member formed in the second contact opening and contacting with the third trench electrode.

9. The semiconductor device according to claim 8, wherein
the plurality of trenches includes a fourth trench formed at a predetermined distance from the third trench,
the plurality of trench electrodes includes a fourth trench electrode formed in the fourth trench, and
a first impurity region is formed in a region of the semiconductor substrate located between the third trench electrode and the fourth trench electrode.

10. The semiconductor device according to claim 8, wherein
the second trench is formed at a predetermined distance from the third trench,
a second impurity region is formed in a region of the semiconductor substrate located between the second trench electrode and the third trench electrode.

11. A manufacturing method of a semiconductor device, comprising the steps of:
(a) preparing a semiconductor substrate having a first main surface and a second main surface opposite to the first main surface;
(b) forming a plurality of trenches in the semiconductor substrate from the first main surface towards the second main surface;
(c) forming a plurality of trench electrodes in each of the plurality of trenches;
(d) an interlayer insulating film formed on the first main surface;
(e) forming a plurality of contact openings penetrating through the interlayer insulating film so as to expose the each of the plurality of trenches;
(f) etching the plurality of trench electrodes exposed in the plurality of contact openings; and
(g) forming a plurality of contact members in each of the plurality of contact openings via a contact barrier metal film, wherein
the step of (b) includes (b1) forming a first trench,
the step of (c) includes (c1) forming a first trench electrode in the first trench,
the step of (e) includes (e1) forming a first contact opening so as to expose the first trench electrode,
in the step of (f), a convex portion of the first trench electrode is formed at a bottom of the first contact opening such that the convex portion protrudes toward the first main surface, and
the step of (g) includes forming a first contact member in the first contact opening via the contact barrier metal film so as to cover the convex portion.

12. The manufacturing method of a semiconductor device according to claim 11, wherein
the step of (c1) include:
(c2) forming a conductive film interposed an oxidation film in the first trench, and
(c3) removing the conductive film and the oxidation film on the first main surface while leaving the conductive film and the oxidation film in the first trench, and
in the step of (f), the conductive film is removed while leaving the oxidation film, thereby the convex portion of the first trench electrode is formed.

13. The manufacturing method of a semiconductor device according to claim 12, wherein
the step of (c2) include (c4) forming the oxidation film as a natural oxidation film.

14. The manufacturing method of a semiconductor device according to claim 11, wherein
in the step of (g), the contact barrier metal film is a material that forms metal silicide by heat treatment.

15. The manufacturing method of a semiconductor device according to claim 11, wherein
the step of (e) is performed by etching using a fluorocarbon gas.

16. The manufacturing method of a semiconductor device according to claim 11, wherein
the step of (f) is performed by etching using a gas includes at least one of chlorine and hydrogen bromide.

17. The manufacturing method of a semiconductor device according to claim 11, wherein
the step of (b) includes (b2) forming a second trench having a width narrower than a width of the first trench,
the step of (c) includes (c5) forming a first trench electrode in the first trench having a width narrower than a width of the first trench electrode.

18. The manufacturing method of a semiconductor device according to claim 12, wherein
the step of (b) includes (b3) forming a third trench formed at a predetermined distance from the first trench,
the step of (c) includes (c6) forming a third trench electrode in the third trench via a trench insulating film
the step of (e) includes (e2) forming a second contact opening so as to expose the third trench electrode, the trench insulating film and a part of the semiconductor substrate,
the step of (f) includes:
(f1) retreating the third trench electrode, the trench insulating film and the part of the semiconductor substrate exposed from the second contact opening respectively in a direction from the first main surface to the second main surface; and
(f2) removing residue left in the first contact opening while leaving the convex portion of the first trench electrode.

19. The manufacturing method of a semiconductor device according to claim 18, wherein
the step of (f2) is performed by etching using a fluorocarbon gas.
